(19) United States
(12) Patent Application Publication
(10) Pub. No.: US 2005/0103441 A1
(43) Pub. Date: May 19, 2005

(54) Etching method and plasma etching apparatus

(76) Inventors: Masanobu Honda, Yamanashi (JP); Kazuya Nagaseki, Yamanashi (JP); Hanako Kida, Yamanashi (JP); Koichi Yatsuda, Nagasaki (JP); Youbun Ito, Hsin-chu City (TW); Koichiro Inazawa, Yamanashi (JP); Rie Inazawa, Yamanashi (JP); Hisataka Hayashi, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/844,498

(22) Filed: May 13, 2004

Related U.S. Application Data
(63) Continuation of application No. PCT/JP02/11844, filed on Nov. 13, 2002.

(30) Foreign Application Priority Data
Nov. 14, 2001 (JP) JP2001-349289
Apr. 17, 2002 (JP) JP2002-115087

(51) Int. Cl. H01L 21/306

(52) U.S. Cl. 156/345.47

(57) ABSTRACT

There is provided an etching method and a plasma etching apparatus capable of taking a large etching selection ratio and of forming a hole having an appropriate shape. When etching an etching target film 204 by using an organic film 202 having a predetermined pattern as a mask, processing gas is introduced into an airtight processing container 104. There are provided a high frequency power source 122 of 40 MHz and a high frequency power source 128 of 3.2 MHz, by which two different kinds of high frequency powers are applied to a lower electrode 106. The power of each high frequency power is properly combined, thereby executing the etching process by using low plasma electron density Ne and high self-bias voltage Vdc which are generated by high frequency power.

### TECHNICAL FIELD

The present invention relates to an etching method and a plasma etching apparatus.

### BACKGROUND TECHNIQUE

At present, in the manufacturing process of semiconductor devices, there is used a technique wherein a predetermined processing of a semiconductor wafer or the like is executed by using plasma formed in an airtight processing container. In this technique using plasma, it becomes one of important subjects how successfully executing the fine and sophisticated processing with high accuracy keeping up with the tendency of high density and high integration in semiconductor device structure.

For example, in an etching process of making a minute structure at a processing target film formed on a semiconductor wafer surface, a processing gas is introduced between a lower electrode capable of serving as a supporting table for supporting the semiconductor wafer placed thereon and an upper electrode facing to the lower one, and a high frequency power is applied to at least one of those two electrodes to form plasma. The processing is executed by means of ions and radicals generated together with electrons in plasma.

FIG. 10 of the accompanying drawings is a schematic sectional view showing the constitution of a plasma etching apparatus 10 as an example of a prior art plasma etching apparatus. FIG. 11 is a schematic sectional view showing the constitution of a plasma etching apparatus 20 as another example of a prior art plasma etching apparatus.

As shown in FIG. 10, the plasma etching apparatus 10 includes an airtight processing container 104 which is grounded, inside which a lower electrode 106 capable of concurrently serving as a supporting table for supporting a semiconductor wafer W mounted thereon is provided such that it can move up and down. The lower electrode 106 is kept at a predetermined temperature by a temperature adjustment mechanism (not shown) and a heat transfer gas at a predetermined pressure is supplied between the semiconductor wafer W and the lower electrode 106 by a heat transfer gas supply mechanism (not shown). An upper electrode 108 is provided such that it opposes to the lower electrode 106 and is grounded through the processing container 104.

In the upper portion of the processing container 104, there is provided a gas introduction hole 132 which is connected with a gas introduction system (not shown) to introduce a predetermined processing gas, for example a mixed gas containing C₄F₆ gas, Ar gas and O₂, into the processing container 104. The introduced processing gas is introduced into the processing chamber 12 through a plurality of gas outlet holes 109.

In the lower portion of the processing container 104, there is provided an exhaust pipe 136 which is connected with an exhaust mechanism (not shown). The inside of the processing container 104 is kept at a predetermined degree of vacuum by evacuating it through the exhaust pipe 136.

Furthermore, there is provided on the side of the processing container 104 a magnet 130 which gives a horizontal magnetic field perpendicular to an electric field. The magnet 130 is constituted such that the strength of the magnetic field is variable. The lower electrode 106 is connected with a high frequency power source 16 through a matcher 14. The frequency of the high frequency power source is 13.56 MHz, for instance.

The processing gas introduced into the processing container 104 is changed into plasma with the high frequency power supplied from the high frequency power source 16 as well as with the horizontal magnetic field caused by the magnet 130, and ions and radicals generated in the plasma are accelerated with self-bias voltage generated in the space in close vicinity to the lower electrode 106 between upper and lower electrodes, thus the etching process of a processing target workpiece (referred to merely as “workpiece” hereinafter) being executed by means of the energy of accelerated ions and radicals.

Furthermore, as shown in FIG. 11, the plasma etching apparatus 20 includes an airtight processing container 4 as grounded, inside which a lower electrode 106 serving as a table supporting a semiconductor wafer W placed thereon is installed such that it can move up and down. The lower electrode 106 is kept at a predetermined temperature by a temperature adjustment mechanism (not shown) and a heat transfer gas having a predetermined pressure is supplied between the semiconductor wafer W and the lower electrode 106 by a heat transfer gas supply mechanism (not shown). An upper electrode 8 is provided in the upper portion of the processing container 4 such that it opposes to the lower electrode 106.

Furthermore, there is formed in the upper portion of the processing container 4 a gas introduction inlet 132 which is connected with a gas introduction system (not shown) to introduce a predetermined processing gas, for example a mixed gas containing C₄F₆ gas, Ar gas and O₂, into the processing container 4. The introduced processing gas is emitted out from a plurality of gas emitting openings 9 toward the processing chamber 2.

In the lower portion of the processing container 4, there is provided an exhaust pipe 36 connected with an exhaust mechanism (not shown). The inside of the processing container 4 is kept at a predetermined degree of vacuum by evacuating the processing container 4 through the exhaust pipe 36.

The upper electrode 8 is connected with a high frequency power source 24 through a matcher 22. The frequency of the high frequency power source 24 is 60 MHz, for instance. The lower electrode 106 is connected with a high frequency power source 28 through a matcher device 26. The frequency of the high frequency power source 28 is 2 MHz, for instance.

The processing gas introduced into the processing container 4 is converted into plasma with these high frequency power supplied from the high frequency power sources 24 and 28, and ions and radicals generated in the plasma are accelerated with the self-bias voltage generated in the space in close vicinity to the lower electrode 106 between upper and lower electrodes, thereby etching of a workpiece being executed with the energy given to accelerated ions and radicals.

FIG. 12 is a graph showing a model of a self-bias voltage Vdc and a plasma electron density Ne in the plasma etching apparatus at the time of etching. An abscissa indicates the self-bias voltage Vdc (V) while an ordinate indicates the plasma electron density Ne (/cm³). An area A indicates the condition when processing is executed by the plasma etching apparatus 10 while an area B indicates the condition when processing is executed by means of the plasma etching apparatus 20.

As will be seen from FIG. 12, in the prior art plasma etching apparatus 10, there has been used an area where the low self-bias voltage Vdc corresponds to the low plasma electron density Ne or the high self-bias voltage Vdc corresponds to the high plasma electron density Ne, in other words, an area where the self-bias voltage Vdc is approximately proportional to the plasma electron density Ne. On the other hand, in the prior art plasma etching apparatus 20, there has been used an area where the plasma electron density Ne is high.

However, when executing the fine and sophisticated etching process by means of the above-mentioned prior art plasma etching apparatus 10 or 20, since the adequate etching selection ratio of a processing target material relative to a mask material can not be secured enough, there is caused such a problem that a hole having a sufficient depth can not be obtained by etching. Even if trying to improve this, there are caused other problems, for example, a problem that the bottom area of a hole can not be adequately obtained relative to the entrance opening area of the hole, a problem that the side wall of a hole as formed becomes tapered, and so forth.

The present invention has been made in view of the above-mentioned problems having been experienced in the prior art etching method and the prior art plasma etching apparatus. Accordingly, an object of the invention is to provide an etching method and a plasma etching apparatus, which are novel and improved.

### DISCLOSURE OF THE INVENTION

According to the result of investigation executed by inventors of the present invention, in case of etching a film made of an organic material (resist), the plasma density plays a dominant part while contribution of the ion energy is small. On one hand, in order to make the etching selection ratio high when etching a film made of an inorganic material (e.g. silicon oxide film), it is necessary to make the plasma density low as well as to make the ion energy high. In this case, since it is possible to indirectly grasp the plasma ion energy by means of a self-bias voltage at the electrode at the time of etching, in order to etch the silicon oxide film at a high etching rate as well as at high etching selection ratio, it is effective to carry out an etching process under the condition of a low plasma density and a high self-bias voltage. If the frequency of the high frequency power applied to the electrode becomes high, a desired plasma density can be obtained with the low power, so that the power consumption is reduced to a great extent.

In order to solve the above-mentioned problems on the basis of the principle as described above, according to an aspect of the invention, there is provided an etching method for etching an etching target film formed at a workpiece including the steps of: introducing a processing gas into an air tight processing container provided with a pair of upper and lower electrodes arranged to oppose to each other; applying the high frequency power to at least one of the upper and lower electrodes, thereby converting the processing gas into plasma; and etching the etching target film formed at the workpiece mounted on the lower electrode by using a mask material patterned in advance as a mask, wherein an electron density in the plasma converted from the processing gas is in a range of 8×10⁹/cm³ to 8×10¹⁰/cm³ less; and the self-bias voltage generated in the space in close vicinity to the lower electrode between the both electrodes is in a range of 2000V to 3000V.

According to the etching method of the invention like this, by executing the etching process at the low plasma electron density as well as at the high self-bias voltage, it becomes possible to make the etching rate of the etching target film large as well as to make the etching selection ratio of the etching target film relative to the mask material film large. Accordingly, it becomes possible to provide the etching target material with fine holes of which each has a flat smooth side surface approximately vertical to the workpiece surface and a bottom area secured enough relative to the entrance opening area of the hole.

Besides, it is preferable that the first high frequency power having the first frequency and the second high frequency power having the second high frequency lower than the first frequency are applied to the lower electrode. In this case, it is also desirous that the first frequency is 40 MHz and the second frequency is 3.2 MHz. Furthermore, it is desirous that the power density of 40 MHz applied to the lower electrode is in a range of 0.32 W/cm² to 3.2 W/cm² or and the power density of 3.2 MHz applied to the lower electrode is in a range of 1.6 W/cm² to 6.4 W/cm².

In order to solve the above-mentioned problems, according to another aspect of the invention, there is provided a etching method for etching an etching target film formed at a workpiece including the steps of: introducing a processing gas into an air tight processing container provided with a pair of upper and lower electrodes arranged to oppose to each other; applying the high frequency power to at least one of the upper and lower electrodes, thereby converting the processing gas into plasma; and etching the etching target film formed at the workpiece mounted on the lower electrode by using a mask material patterned in advance as a mask,
wherein there are applied to the lower electrode the first high frequency power having the first frequency of 40 MHz, of which the power density is in a range of 0.32 W/cm² to 3.2 W/cm² and the second high frequency power having the second high frequency of 3.2 MHz, of which the power density is in a range of 1.6 W/cm² to 6.4 W/cm².

According to the etching method like this of the invention, by applying the high frequency power of 2-system having different frequencies (e.g. the first frequency of 40 MHz and the second frequency of 3.2 MHz) to the lower electrode of the plasma etching apparatus, the etching process can be executed by means of the low plasma electron density and the high self-bias voltage.

An etching target film may be a silicon contained oxide film. Furthermore, the above etching may be executed such that the silicon contained oxide film is selectively etched relative to a silicon nitride film.

In order to solve the above-mentioned problems, according to another aspect of the invention, there is provided a plasma etching apparatus in which a processing gas is introduced into an air tight processing container provided with a pair of upper and lower electrodes arranged to oppose to each other, the high frequency power is applied to at least one of the upper and lower electrodes, thereby converting the processing gas into plasma, and the etching target film formed at the workpiece mounted on the lower electrode is etched by using a mask material patterned in advance as a mask,
wherein a plasma electron density in the plasma converted from the processing gas is in a range of 8×10⁹/cm³ to 8×10¹⁰/cm³ less, the self-bias voltage generated in the space in close vicinity to the lower electrode between the both electrodes is in a range of 2000V to 3000V, and there are applied to the lower electrode the first high frequency power having the first frequency and the second high frequency power having the second high frequency lower than the first frequency.

According to the etching apparatus of the invention like this, by executing the etching process by means of the low plasma electron density and the high self-bias voltage, it is become possible to make the etching rate of the etching target film large as well as to make the etching selection ratio of the etching target film relative to the mask material film large. Accordingly, it becomes possible to provide the etching target material with fine holes of which each has a flat smooth side surface approximately vertical to the workpiece surface and a bottom area secured enough relative to the opening area of the hole.

Besides, it is preferable that the first frequency is 40 MHz and the second frequency is 3.2 MHz. It is also preferable that the power density of 40 MHz applied to the lower electrode is in a range of 0.32 W/cm² to 3.2 W/cm² and the power density of 3.2 MHz applied to the lower electrode is in a rage of 1.6 W/cm² to 6.4 W/cm².

In order to solve the above-mentioned problems, according to another aspect of the invention, there is provided a plasma etching apparatus in which a processing gas is introduced into an air tight processing container provided with a pair of upper and lower electrodes arranged to oppose to each other, the high frequency power is applied to at least one of the upper and lower electrodes, thereby converting the processing gas into plasma, and the etching target film formed at the workpiece mounted on the lower electrode is etched by using a mask material patterned in advance as a mask,
wherein there are applied to the lower electrode the first high frequency power having the first frequency of 40 MHz, of which the power density is in a range of 0.32 W/cm² to 3.2 W/cm² and the second high frequency power having the second high frequency of 3.2 MHz, of which the power density is in a range of 1.6 W/cm² to 6.4 W/cm².

According to the etching apparatus of the invention like this, by applying the high frequency power of 2-system having different frequencies (e.g. the first frequency of 40 MHz and the second frequency of 3.2 MHz), to the lower electrode, the etching process can be executed by means of the low plasma electron density and the high self-bias voltage.

In order to solve the above-mentioned problems, according to another aspect of the invention, there is provided an etching method for etching an etching target film formed at a workpiece including the steps of: introducing a processing gas into an air tight processing container provided with a pair of upper and lower electrodes arranged to oppose to each other; applying the high frequency power to at least one of the upper and lower electrodes, thereby converting the processing gas into plasma; and etching the etching target film formed at the workpiece mounted on the lower electrode by using a mask material patterned in advance as a mask,
wherein an electron density in the plasma converted from the processing gas is in a range of 1×10¹⁰/cm³ to 8×10¹⁰/cm³ less; and the self-bias voltage generated in the space in close vicinity to the lower electrode between the both electrodes is in a range of 1000V to 3000V.

According to the etching method of the invention like this, by executing the etching process by means of the low plasma electron density and the high self-bias voltage, it is become possible to make the etching rate of the etching target film large as well as to make the etching selection ratio of the etching target film relative to the mask material film large. Accordingly, it becomes possible to provide the etching target material with fine holes of which each has a flat smooth side surface approximately vertical to the workpiece surface and a bottom area secured enough relative to the entrance opening area of the hole.

Besides, it is preferable that there are applied to the lower electrode the first high frequency power having the first frequency and the second high frequency power having the second high frequency lower than the first frequency. In this case, it is desirous that the first frequency is 100 MHz and the second frequency is 3.2 MHz. It is also desirous that the power density of 100 MHz applied to the lower electrode is in a range of 0.13 W/cm² to 1.4 W/cm² and the power density of 3.2 MHz applied to the lower electrode is in a range of 2.7 W/cm² to 8.2 W/cm².

In order to solve the above-mentioned problems, according to another aspect of the invention, there is provided an etching method for etching an etching target film formed at a workpiece including the steps of: introducing a processing gas into an air tight processing container provided with a pair of upper and lower electrodes arranged to oppose to each other; applying the high frequency power to at least one of the upper and lower electrodes, thereby converting the processing gas into plasma; and etching the etching target film formed at the workpiece mounted on the lower electrode by using a mask material patterned in advance as a mask,
wherein there are applied to the lower electrode the first high frequency power having the first frequency of 100 MHz, of which the power density is in a range of 0.13 W/cm² to 1.4 W/cm² or less and the second high frequency power having the second high frequency of 3.2 MHz, of which the power density is in a range of 2.7 W/cm² to 8.2 W/cm².

According to the etching method of the invention like this, by applying the high frequency power of 2-system having different frequencies (e.g. the first frequency of 100 MHz and the second frequency of 3.2 MHz) to the lower electrode of the plasma etching apparatus, the etching process can be executed by means of the low plasma electron density and the high self-bias voltage.

The aforesaid mask material may be a film made of an organic matter, which may be a resist. The aforesaid etching target film may be an inorganic insulating film.

In order to solve the above-mentioned problems, according to another aspect of the invention, there is provided a plasma etching apparatus in which a processing gas is introduced into an air tight processing container provided with a pair of upper and lower electrodes arranged to oppose to each other, the high frequency power is applied to at least one of the upper and lower electrodes, thereby converting the processing gas into plasma, and the etching target film formed at the workpiece mounted on the lower electrode is etched by using a mask material patterned in advance as a mask,
wherein an electron density in the plasma converted from the processing gas is in a range of 1×10¹⁰/cm³ to 8×10¹⁰/cm³, the self-bias voltage generated in the space in close vicinity to the lower electrode between the both electrodes is in a range of 1000V to 3000V, and there is applied to the lower electrode the first high frequency power having the first frequency and the second high frequency power having the second high frequency lower than the first frequency.

According to the etching apparatus of the invention like this, by executing the etching process by means of the low plasma electron density and the high self-bias voltage, it is become possible to make the etching rate of the etching target film large as well as to make the etching selection ratio of the etching target film relative to the mask material film large. Accordingly, it becomes possible to provide the etching target material with fine holes of which each has a flat smooth side surface approximately vertical to the workpiece surface and a bottom area secured enough relative to the entrance opening area of the hole.

Besides, it is preferable that the aforesaid first frequency is 100 MHz and the aforesaid second frequency is 3.2 MHz. Also, it is desirable that the power density of 100 MHz applied to the lower electrode is in a range of 0.13 W/cm² to 1.4 W/cm² and the power density of 3.2 MHz applied to the lower electrode is in a range of 2.7 W/cm² to 8.2 W/cm².

In order to solve the above-mentioned problems, according to another aspect of the invention, there is provided a plasma etching apparatus in which a processing gas is introduced into an air tight processing container provided with a pair of upper and lower electrodes arranged to oppose to each other, the high frequency power is applied to at least one of the upper and lower electrodes, thereby converting the processing gas into plasma, and the etching target film formed at the workpiece mounted on the lower electrode is etched by using a mask material patterned in advance as a mask,
wherein there are applied to the lower electrode the first high frequency power having the first frequency of 100 MHz, of which the power density is in a range of 0.13 W/cm² to 1.4 W/cm² and the second high frequency power having the second high frequency of 3.2 MHz, of which the power density is in a range of 2.7 W/cm² to 8.2 W/cm².

According to the etching method of the invention like this, by applying the high frequency power of 2-system having different frequencies (e.g. the first frequency of 100 MHz and the second frequency of 3.2 MHz) to the lower electrode of the plasma etching apparatus, the etching process can be executed by means of the low plasma electron density and the high self-bias voltage.

In this specification, the power density of high frequency power means an amount of high frequency power applied to a unit area of the electrode. Also, in this specification, 1 mTorr is (10⁻³×101325/760) Pa, and 1 sccm is (10⁻⁶/60) m³/sec.

### BRIEF DESCRIPTION OF THE DRAWINGS

FIG. 1 is a schematic sectional view showing the constitution of a plasma etching apparatus 100 according to the first embodiment of the invention.

FIG. 2 is a schematic sectional view showing the structure of a workpiece 200 as processed in the same embodiment as the above.

FIG. 3 is a table comparatively showing results of etching by means of respective plasma etching apparatus when a resist for use in an X-ray is adopted to form a mask layer 202.

FIG. 4 is a table comparatively showing result of etching by means of respective plasma etching apparatus when a resist for use in an ArF excimer laser with a wavelength of 193 nm is adopted to form a mask layer 202.

FIG. 5 is a table showing values of plasma electron density Ne and self-bias voltage Vdc which varies depending on etching conditions adopted in respective plasma etching apparatus.

FIG. 6 is a graphical representation showing magnetic field dependency of etching results.

FIG. 7 is a table showing magnetic field dependency of etching results.

FIG. 8 is a table showing applied power dependency of etching results.

FIG. 9 is a table showing etching conditions adopted in respective plasma etching apparatus.

FIG. 10 is a schematic sectional view showing the constitution of a prior art plasma etching apparatus 10.

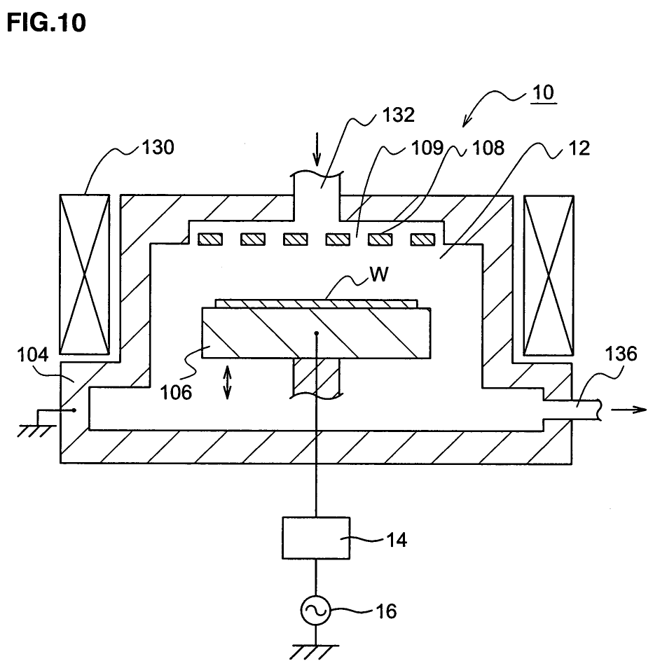

FIG. 11 is a schematic sectional view showing the constitution of a prior art plasma etching apparatus 20.

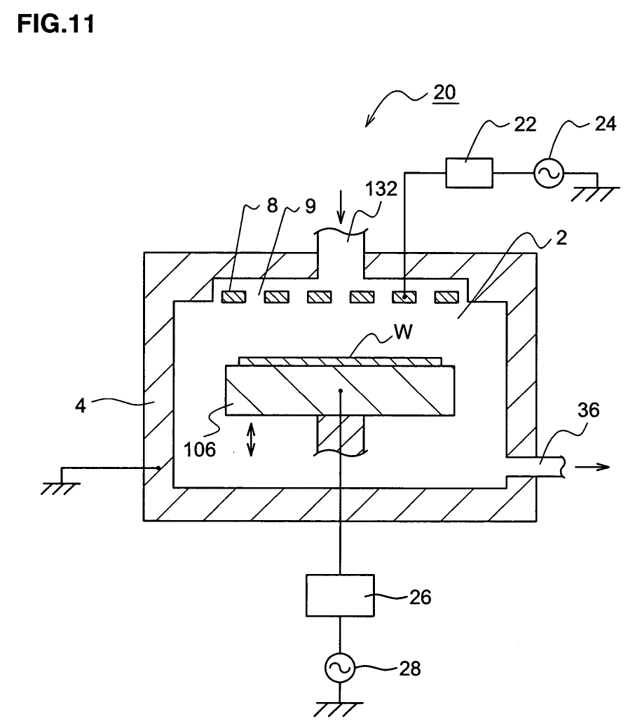

FIG. 12 is a graphical representation showing the self-bias voltage Vdc and the plasma electron density Ne at the time of etching within the plasma etching apparatus.

FIG. 13 is a graphical representation showing the self-bias voltage Vdc and the plasma electron density Ne at the time of etching executed in the plasma etching apparatus.

FIG. 14 is a schematic sectional view showing the structure of a workpiece 300 as processed in the same embodiment as the above.

FIG. 15 is a table comparatively showing results of etching experiments wherein high frequency powers of 40 MHz and 3.2 MHz are applied to a lower electrode, respectively.

FIG. 16 is a graphical representation showing the self-bias voltage Vdc and the plasma electron density Ne at the time of etching within a plasma etching apparatus according to the second embodiment of the invention.

FIG. 17 is a contour map indicative of etching rates and etching selection ratio.

FIG. 18 is a contour map indicative of etching rates and etching selection ratio.

FIG. 19 is a graphical representation showing a relation between a plasma gas flow rate and a pressure difference Ap between the center portion and the peripheral portion of a wafer, wherein Ar gas is used a plasma gas and the electrode gaps of 25 mm and 40 mm are used as parameters.

### BEST MODE TO EXECUTE THE INVENTION

The invention will now be described in detail by way of preferred embodiments in the following with reference to the accompanying drawings. In this specification as well as in these drawings, constituents of the invention having substantially identical function and constitution will be denoted with identical reference numerals, characters, or marks, thereby omitting repetitive redundant descriptions thereabout.

### First Embodiment

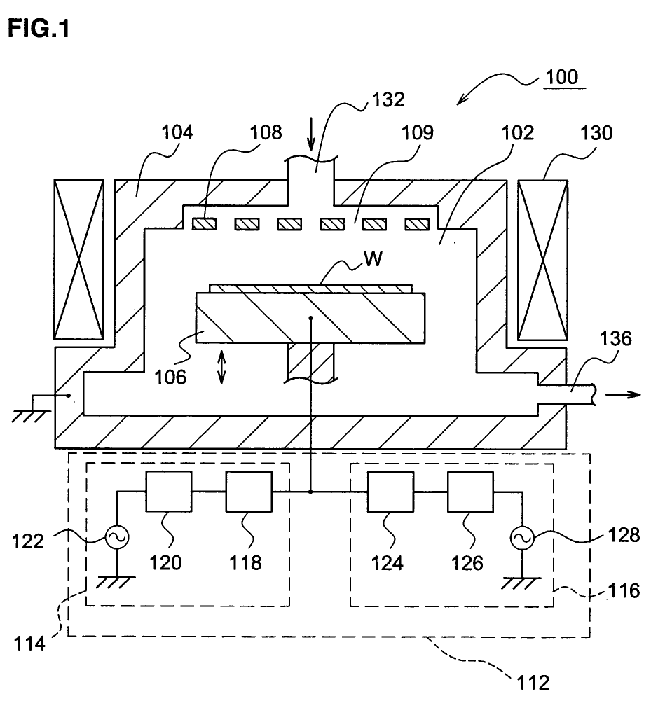

First of all, the constitution of a plasma etching apparatus according to an embodiment of the invention will be described with reference to the accompanying drawings. FIG. 1 is a schematic sectional view showing the constitution of a plasma etching apparatus 100 according to the first embodiment of the invention.

As shown in FIG. 1, the plasma etching apparatus 100 has an air tight processing container 104 which is grounded. A processing chamber 102 is formed inside the processing container 104. In the processing chamber 102, a lower electrode 106 capable of concurrently serving as a supporting table for supporting a workpiece such as a semiconductor wafer W mounted thereon, is arranged such that it can move up and down. The lower electrode 106 is kept at a predetermined temperature by means of a temperature adjustment mechanism (not shown), and a heat transfer gas at a predetermined pressure is supplied between the semiconductor wafer W and the lower electrode 106 by means of a heat transfer gas supply mechanism (not shown). An upper electrode 108 is formed in a position opposing to the surface of the lower electrode 106, on which a workpiece is mounted. In an example as shown, the upper electrode 108 is grounded through the processing container 104.

Furthermore, in the upper portion of the processing container 104, there is formed a gas introduction hole 132 which is connected with a gas introduction system (not shown) to introduce a predetermined processing gas into the processing container 104. The processing gas introduced into the processing container 104 is in turn introduced into the processing chamber 102 through a plurality of gas outlet holes 109 formed in the upper electrode 108. The processing gas may be a mixed gas containing C₄F₆ gas, Ar gas and O₂ gas, for example.

In the lower portion of the processing container 104, there is provided an exhaust pipe 136 connected with an exhaust mechanism (not shown). By vacuuming the processing container 104 through this exhaust pipe 136, the inside of the processing container 104 is kept at a predetermined degree of vacuum, for example at 50 mTorr. Furthermore, there is provided on the outside of the processing container 104 a magnet 130, which gives a horizontal magnetic field perpendicular to an electric field. The magnet 130 is constituted such that the magnetic field strength of the magnet 130 is variable.

The lower electrode 106 is connected with a power supply apparatus 112 supplying a 2-fequency superposed power. The power supply apparatus 112 is made up of the first power supply mechanism 114 supplying the high frequency power at the first frequency and the second power supply mechanism 116 supplying the high frequency power at the second frequency which is lower than the first frequency.

The first power supply mechanism 114 has the first filter 118, the first matcher 120 and the first power source 122 which are sequentially connected with the lower electrode 106 in this order. The first filter 118 prevents a power component of the second frequency from intruding into the first matcher 120. The first matcher 120 takes matching of the first high frequency power component. The first frequency is 40 MHz, for example.

The second power supply mechanism 116 has the second filter 124, the second matcher 126 and the second power source 128 which are sequentially connected with the lower electrode 106 in this order. The first filter 118 prevents a power component of the first frequency from intruding into the second matcher 120. The second matcher 126 takes matching of the second high frequency power component. The second frequency is 2 MHz, for example.

In the plasma etching apparatus 100 as constituted above, the processing gas introduced into the processing container 104 is converted into plasma with the high frequency power of two kinds as supplied from the power supply apparatus 112 as well as with the horizontal magnetic field caused by the magnet 130, and ions and radicals generated in the plasma are accelerated with the self-bias voltage generated between the electrodes, thus an etching process of a workpiece being executed by means of the energy of accelerated ions and radicals.

(Structure of Workpiece)

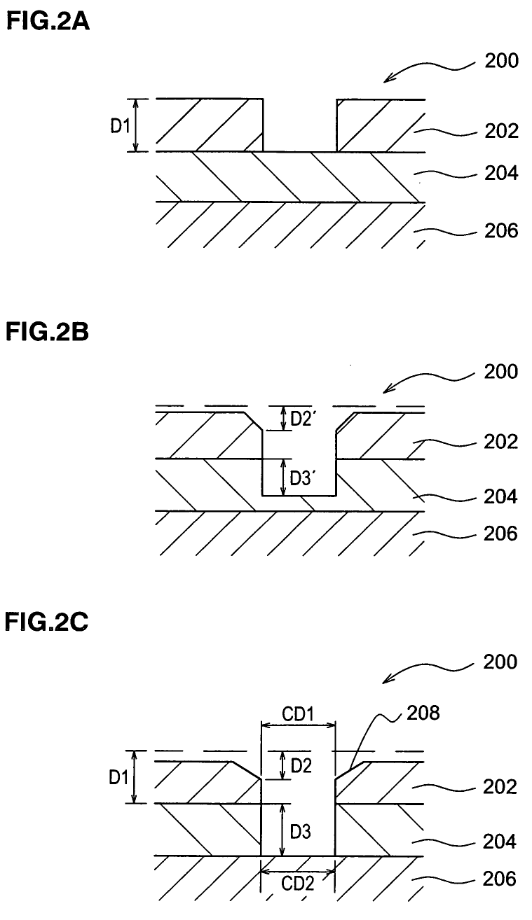

In the next, there will be explained the structure of a workpiece having an etching target film, which is used in this embodiment. FIG. 2 is a schematic sectional view showing the structure of a workpiece 200 according to this embodiment. FIG. 2A is a sectional view of the workpiece on which any etching process according to this embodiment is not executed yet. FIG. 2B is a sectional view of the workpiece while the above etching process is being executed. FIG. 2C is a sectional view of the workpiece when the above etching process has been completed.

As shown in FIG. 2A, the workpiece 200 is made up of a mask layer 202 which is formed by means of a lithographic technique to have a predetermined pattern, and an etching target layer 204 which lies under the mask layer 202 as well as over a silicon substrate 206. The mask layer 202 is made of a resist for use in the X-ray or the excimer laser. The etching target layer 204 is made of a silicon oxide film, but it may be made of the silicon oxide film which is doped with boron or phosphorus. Furthermore, the workpiece may have a structure that a film made of another material intervenes between the mask layer 202 and the etching target layer 204.

If the workpiece 200 like this is etched by the etching process according to the embodiment, there is formed a hole having a dimension as shown in FIG. 2C, that is, a hole diameter CD1 (referred to as “top CD” hereinafter), a hole bottom diameter CD2 (referred to as “bottom CD” hereinafter), and a depth D3 which is a depth from the surface of the etching target layer 204. At this time, the mask layer 202 comes to be most removed from a shoulder portion 208 near an entrance of the hole up to a depth D2.

(Apparatus Dependency of Etching Result)

In the next, there will be explained the results of etching process applied to such a workpiece 200 as described above by means of the plasma etching apparatus 100 according to the present embodiment and prior art plasma etching apparatus 10 and 20.

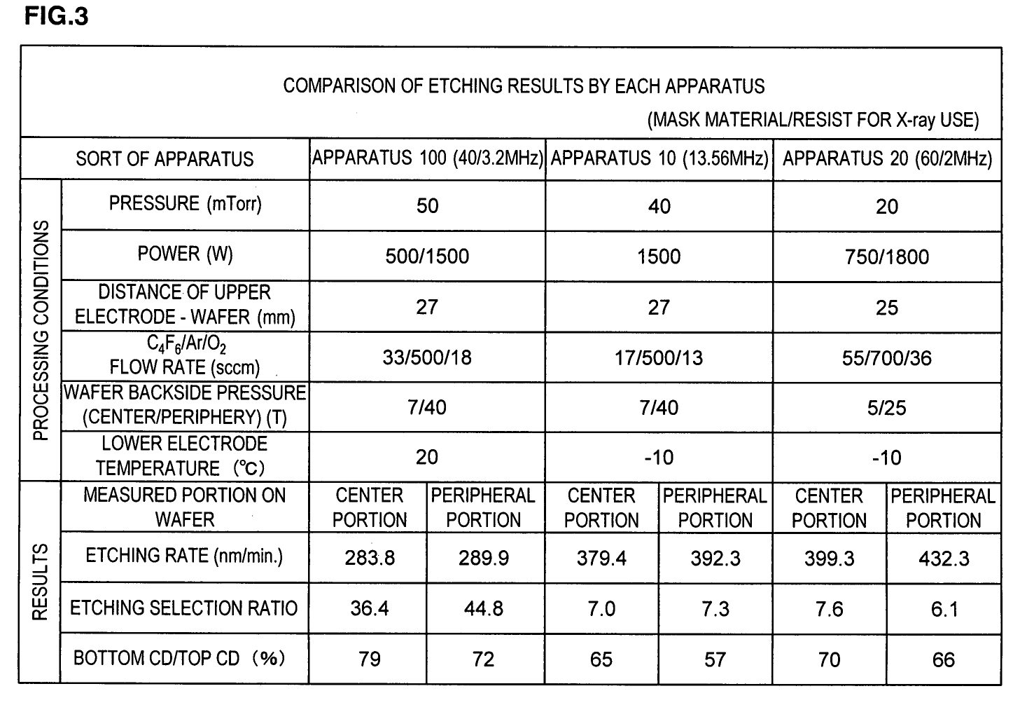

FIG. 3 is a table showing comparison of etching results by each plasma etching apparatus using a workpiece wherein an etching target layer 204 is a silicon oxide film of 2100 nm thick formed on a silicon substrate by thermal oxidation, a mask layer 202 of 650 nm thick is made of a resist for use in the X-ray and is provided with a hole pattern of φ0.15 μm. As shown in FIG. 3, although each value of pressure inside the processing container, high frequency power, distance between upper electrode and semiconductor wafer, heat transfer gas pressure at backside surface of semiconductor, and lower electrode temperature is different from plasma etching apparatus to plasma etching apparatus, this is for optimizing the etching process by each plasma etching apparatus. Processing gas is made identical with respect to all the plasma etching apparatus. The sorts of processing gases are made identical and a mixed gas containing C₄F₆ gas, Ar gas and O₂ gas is used. Let the over-etching be allowed up to 30% in all the cases.

To additionally put the processing conditions by the plasma etching apparatus 100, for example, with reference to the table as shown in FIG. 3, the flow rates of C₄F₆ gas, Ar gas and O₂ gas are set to 33 seccm, 500 seccm, and 18 seccm, respectively. The pressure in the processing container is set to 50 mTorr. The powers to be applied are set to 40 MHz 500 W and 3.2 MHz 1500 W. The distance between the upper electrode and the workpiece i.e. the semiconductor wafer surface is set to 27 mm. The pressure of heat transfer gas applied to the backside surface of the semiconductor wafer is set to 7 Torr at its center portion and 70 Torr at its peripheral portion. The temperature of the lower electrode 106 is set to 20° C.

After the etching process of a workpiece made of a semiconductor wafer of 200 mm diameter was executed by each plasma etching apparatus, there were measured various values such as an etching rate, and etching selection ratio, and a bottom CD/top CD value. The etching selection ratio means a ratio of the etching rate of the etching target layer 204 to that of the mask layer 202, in other words, it is expressed as D3′/D2′ in terms of parameters shown in FIG. 2B. The bottom CD/top CD value is one of values indicative of the shape of the hole, in other words, it is expressed as CD2/CD1 in terms of parameters shown in FIG. 2C.

According to the results of the above measurement, the etching rate sequentially becomes higher in the order of the plasma etching apparatus (referred to as merely “apparatus” hereinafter) 20, the apparatus 10, and the apparatus 100. In the same period of time, the higher the etching rate is, the deeper the etching depth becomes. However, the apparatus 100 indicates the highest value with regard to the etching selection ratio and the bottom CD/top CD value.

If the etching selection ratio is low, there might be brought such a risky state that even if the etching rate is high, the mask layer 202 is broken before a desired depth of the hole is secured. Accordingly, in order to execute the etching process for forming a deep hole without causing the breakdown of the mask layer 202, it is needed that the etching selection ratio is high. A high value of bottom CD/top CD indicates that there is formed a hole having a bottom area secured enough relative to the entrance opening area of the hole. Accordingly, this is preferable.

From the results as described above, it is learned that especially in the etching selection ratio, two apparatus 10 and 20 indicate a value of 7 or so while the apparatus 100 indicates very high values of 30 through 40. Accordingly it can be understood that the apparatus 100 is a useful apparatus to be used when it is needed to achieve a large etching selection ratio in the etching process. In the observation of the sectional shape of the hole, it is recognized that the apparatus 100 can secure the bottom CD/top CD value of 70% or more. Accordingly, it is apparent that the apparatus 100 holds a dominant position comparing with the apparatus 10 and 20.

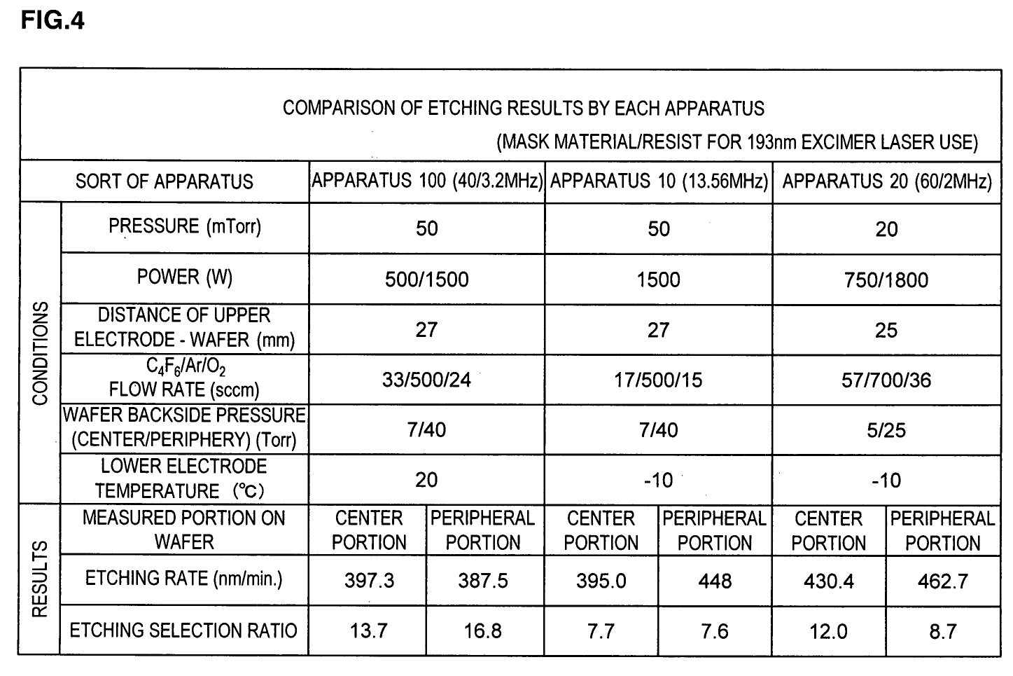

FIG. 4 is a table showing comparison of etching results by each apparatus using a workpiece wherein an etching target layer 204 is a silicon oxide film of 2000 nm thick formed on a silicon substrate by CVD, a mask layer 202 of 400 nm thick is made of a resist for use in the ArF excimer laser of 193 nm wavelength and is provided with a hole pattern of 0.2 μm. As shown in FIG. 4, although each value of pressure inside the processing container, high frequency power, distance between upper electrode and semiconductor wafer, heat transfer gas pressure at backside surface of semiconductor, and lower electrode temperature is different from the apparatus to the apparatus, this is for optimizing the etching process by each apparatus. Processing gas is made identical with respect to all the plasma etching apparatus. The etching time is set to 240 sec with regard to all the apparatus and the etching condition is set such that the silicon substrate is not exposed.

To additionally put the processing conditions by the apparatus 100, for example, with reference to the table as shown in FIG. 4, the flow rates of C₄F₆ gas, Ar gas and O₂ gas are set to 33 seccm, 500 seccm, and 24 seccm, respectively. The pressure in the processing container is set to 50 mTorr. The powers to be applied are set to 40 MHz 500 W and 3.2 MHz 1500 W. The distance between the upper electrode and the workpiece i.e. the semiconductor wafer surface is set to 27 mm. The pressure of heat transfer gas applied to the backside surface of the semiconductor wafer is set to 7 Torr at its center portion and 40 Torr at its peripheral portion. The temperature of the lower electrode 106 is set to 20° C. With respect to the structure of the workpiece, each measurement item and the same part as shown in FIG. 3, the repetitive explanation will be omitted in the following.

According to the results of the above measurement, the etching rate sequentially becomes higher in the order of the apparatus 20, the apparatus 10 and the apparatus 100. In the same period of time, the higher the etching rate is, the deeper the etching depth becomes. However, the apparatus 100 indicates the highest value with regard to the etching selection ratio. As described before, in order to carry out the etching process of forming a deep hole without causing the breakdown of the mask layer 202, it is important that the etching selection ratio is high.

From the results as described above, it is learned that especially as to the etching selection ratio, the apparatus 100 indicates a high value which is approximately double at maximum comparing with apparatus 10 and 20. Accordingly, it can be understood that the apparatus 100 is a useful apparatus to be used when it is needed to achieve a large etching selection ratio in the etching process.

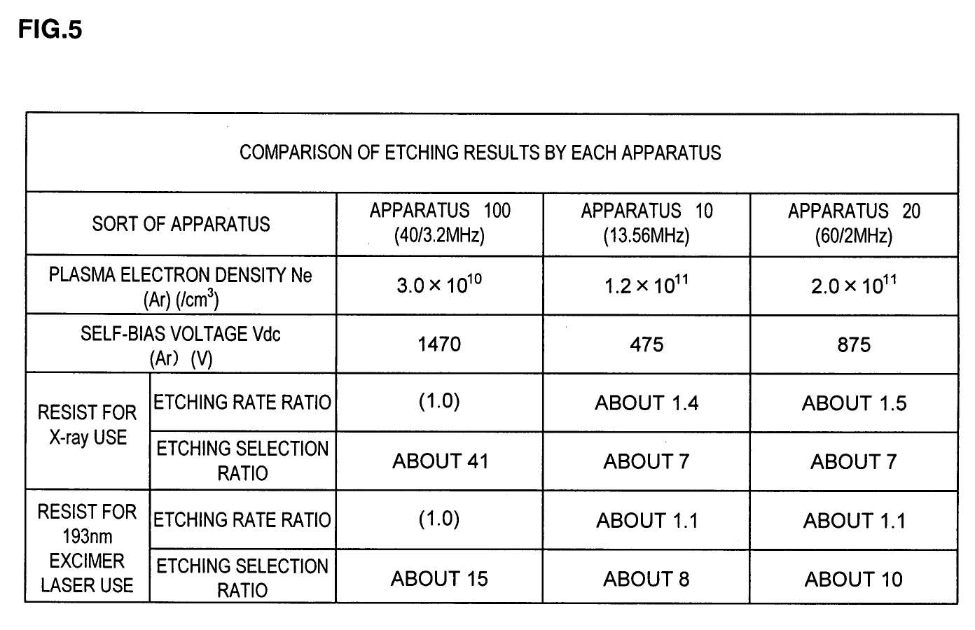

FIG. 5 is a table which is made by getting together the results as shown in FIGS. 3 and 4. This table shows the plasma electron density Ne and the self-bias voltage Vdc at the time when the etching process is executed under the etching conditions adopted by each apparatus as shown in FIGS. 3 and 4.

In the apparatus 100, when supplying only Ar gas on behalf of the processing gas, the plasma electron density Ne is 3.0×10⁻¹⁰/cm³ and the self-bias voltage Vdc is 1470V. In the apparatus 10, when supplying only Ar gas on behalf of the processing gas, the plasma electron density Ne is 1.2×10⁻¹⁰/cm³ and the self-bias voltage Vdc is 475V. In the apparatus 20, when supplying only Ar gas on behalf of the processing gas, the plasma electron density Ne is 2.0×10⁻¹⁰/cm³ and the self-bias voltage Vdc is 875V. Respective values of the plasma electron density Ne and the self-bias voltage Vdc in case of supplying the processing gas are different from those in case of supplying only Ar gas, but both indicate relatively same tendency and values in the latter case i.e. values in case of supplying only Ar gas becomes larger than the former. The plasma electron density in case of supplying the processing gas will be described later.

At this time, the etching rate in case of using the resist for use in the X-ray is about 1.4 in the apparatus 10 and about 1.5 in the apparatus 20, respectively, relative to the etching rate in the apparatus 100 as standard. On the other hand, the etching rate in case of using the resist for use in the excimer laser is about 1.1 in the apparatus 10 and about 1.1 in the apparatus 20.

The etching selection rate in case of using the resist for use in the X-ray is about 41 in the apparatus 100, about 7 in the apparatus 10 and about 7 in the apparatus 20, respectively. On the other hand, the etching selection rate in case of using the resist for use in the excimer laser is about 15 in the apparatus 100, about 8 in the apparatus 10 and about 20 in the apparatus 20, respectively.

As will be seen from the results as described above, the apparatus 100 makes it possible to make the etching selection ratio larger than the apparatus 10 and 20 regardless of the resist as used. At this time, comparing three apparatus with each other by using respective values in case of using Ar gas, the plasma electron density Ne in the apparatus 100 is lower than that in both of apparatus 10 and 20 while the self-bias voltage Vdc becomes higher than that in both of apparatus 10 and 20. In general, when making the plasma electron density large, the self-bias voltage becomes small.

Accordingly, when etching the etching target film 204 such as a silicon oxide film including a dopant by using an organic film made of the resist for use in the X-ray or the excimer laser as a mask layer 202 and supplying only Ar gas, it is preferable to carry out the etching process under the condition wherein the low plasma electron density Ne is low, for example 1.0×10¹¹/cm³ or less, preferably 3.0×10¹⁰/cm³ or less and a self-bias voltage Vdc is high, for example 500V or more, preferably 900V or more. It is practical to set the upper limit of the self-bias voltage Vdc to 2000V or less, preferably 1600V or less in view of etching selection ratio, because if the self-bias voltage Vdc is too high, the etching selection ratio is reduced.

(Magnetic Field Dependency of Etching Result)

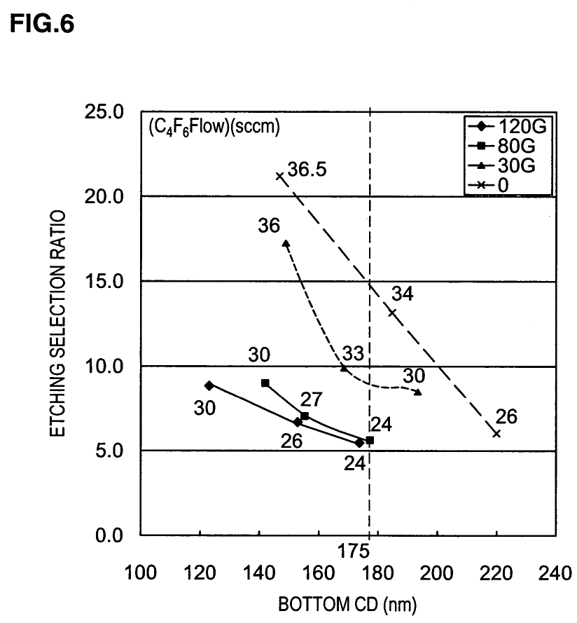

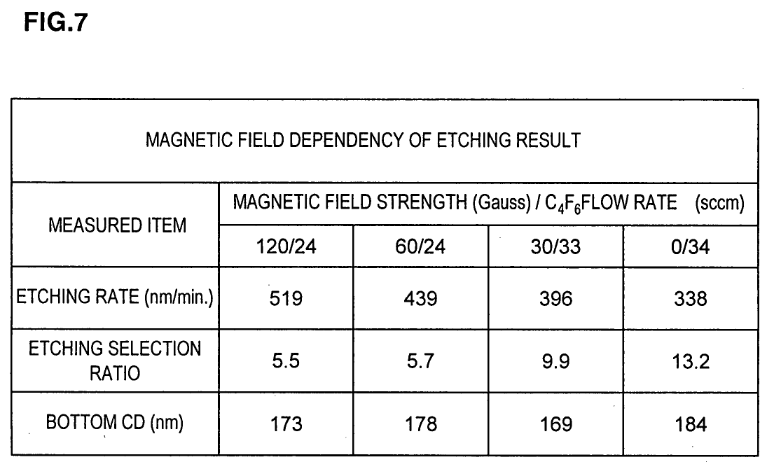

In the next, there will be explained the horizontal magnetic field strength dependency of the etching result. FIGS. 6 and 7 are graphical representations showing magnetic field dependency of the etching result. In a workpiece as used here, an etching target layer 204 is a silicon oxide film (BSG) of 5000 nm thick which is formed on a silicon nitride (SiN) film layer by CVD system and a mask layer 202 is an organic mask of 900 nm thick which is formed by multi-layer resist process to have a hole pattern of φ0.17 μm. After executing the etching process on this workpiece by changing the flow rate of the processing gas C₄F₆ with respect to each magnetic field strength of 120, 60, 30 and 0 gauss, there was examined the change in the bottom CD and the etching selection ratio as well. The over-etching rate is made to be 40% in all the cases.

Common etching conditions at this time are as follows. The pressure inside the processing container is set to 40 mTorr, the temperatures of the upper electrode 108 and the inside wall of the processing container 104 equally set to 60° C. The temperature of the lower electrode is adjusted along with the heat transfer gas pressure at the backside surface of the wafer (e.g. backside gas pressure at the center portion as well as at peripheral portion of the wafer) such that the temperature of the wafer becomes 140° C. to 150° C. on every condition. The power to be applied is 40 MHz 450 W and 3.2 MHz 1800 W. A distance between the upper electrode 108 and a wafer is set to 27 mm. In this case, the etching process is executed by changing the flow rate of C₄F₆ gas relative to Ar gas of 500 sccm and O₂ gas of 20 sccm in each processing gas and, and then, the bottom CD and the etching selection ratio are measured.

In FIG. 6, an abscissa represents the bottom CD (nm) and an ordinate represents the etching selection ratio. A numeral put near each plot indicates the flow rate of the C₄F₆ gas. If changing the magnetic field strength at the center portion of the semiconductor wafer in order of 0, 30, 60, and 120 Gauss, the bottom CD can take a large value but the etching selection ratio has a tendency to go down, when the flow rate of C₄F₆ gas is small and the flow rate ratio of 02 gas is large.

In case of the flow rate condition of C₄F₆ gas that the same bottom CD can be obtained, if the magnetic field strength is weak, the etching rate becomes low but the etching selection ratio becomes high. Accordingly, it is understood that an etching condition moves in a preferable direction. In other words, if the magnetic field strength becomes small, the electron confinement effect becomes small and electrons are absorbed into the ground. As the result of this, the plasma electron density Ne goes down and the electron temperature goes up. This electron temperature rise causes active movement of electrons and electrons can come into the lower electrode 106 with ease, thus the self-bias voltage Vdc becoming high. In short, if the magnetic field strength is made small, the plasma electron density Ne becomes low and the self-bias voltage Vdc becomes high. This is preferable as the etching condition. Furthermore, In case of the flow rate condition of C₄F₆ gas that the same etching selection ratio can be obtained, as the bottom CD can take a large value, it becomes a preferable etching condition that the plasma electron density Ne is high and the self-bias voltage Vdc is low.

FIG. 7 shows various values of etching rate, etching selection ratio and bottom CD at the time when a bottom CD takes an approximately equivalent value (in the vicinity of 175 nm) as indicated by a vertical broken line in FIG. 6. Like this, when the magnetic field strength is zero and the flow rate of O₂ gas is 34 sccm, the etching selection ratio relative to the resist for use in the ArF excimer laser could take a large value. At this time, the plasma electron density Ne and the self-bias voltage Vdc were 1.0×10¹⁰/cm³ and 1200V, respectively, in the state that only Ar gas was supplied. For practical standpoint of view, since it is necessary for the etching selection ratio to be secured at a value of 10 or more, it is preferable that the magnetic field strength is 30 Gauss or less by taking account of respective values of etching rate and bottom CD as well.

(Applied Power Dependency of Etching Result)

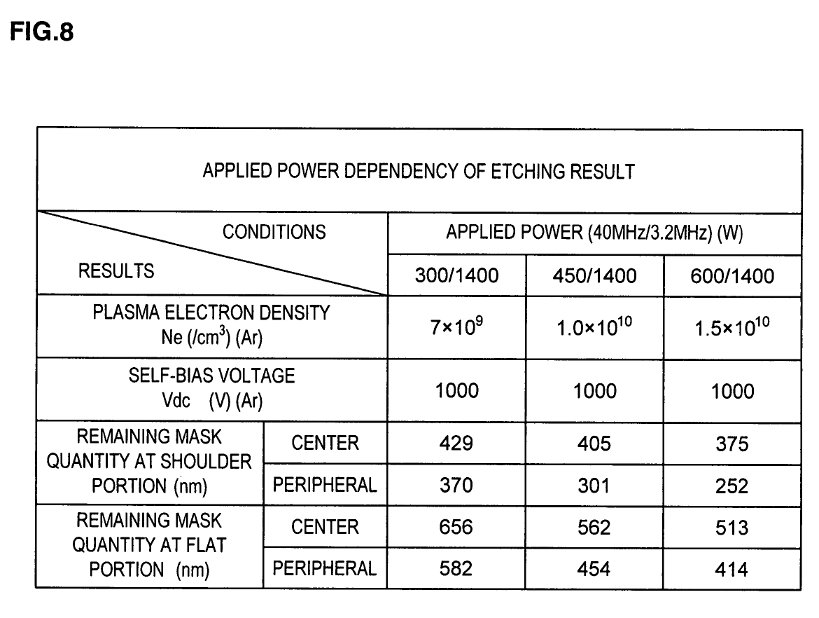

In the next, the applied power dependency of etching result will be explained by way of the case where the magnetic field strength is zero at the center portion of a semiconductor wafer. FIG. 8 is a table showing applied power dependency of etching results. The structure of a processing workpiece as used herein is identical to that of the workpiece in case of FIG. 7. Besides, a distance between the upper electrode 108 and the wafer is set to 27 mm and let the over-etching be allowed up to 30% in all the cases.

As shown in FIG. 8, in apparatus 100, the pressure inside the processing container is set to 60 mmTorr. Each temperature of the upper electrode 108, the inside wall of the processing container and the lower electrode is set to 60° C., 60° C., 30° C., respectively. Each flow rate of the processing gas i.e. C₄F₆ gas, Ar gas and O₂ gas is set to 30 sccm, 500 sccm and 20 sccm, respectively. The etching process is executed by using such an applied power that is obtained by changing the power given from the high frequency power source 122 of 40 MHz to respective powers of 300 W (0.96 W/cm²), 450 W (1.4 W/cm²) and 600 W (1.9 W/cm²), relative to the power of 3.2 MHz 1400 W (4.5 W/cm²). After completing each etching process, there was examined the remaining film thickness of the mask layer 202.

From the above result, it is learned that the lower the applied power is, the larger the amount of the resist remaining at the shoulder portion as well as at flat portion is. At this time, if the plasma electron density Ne is within a range of 7×10⁹/cm³ to 1.5×10¹⁰/cm³ under the condition that only Ar gas is supplied and similarly the self-bias voltage Vdc is 1000V under the same condition, it is deemed this is practically viable. If the plasma electron density Ne is too small, the etching rate goes down so that the plasma electron density Ne is to be 7×10⁹/cm³ or more, preferably 5×10⁹/cm³.

(Plasma State at Etching Time)

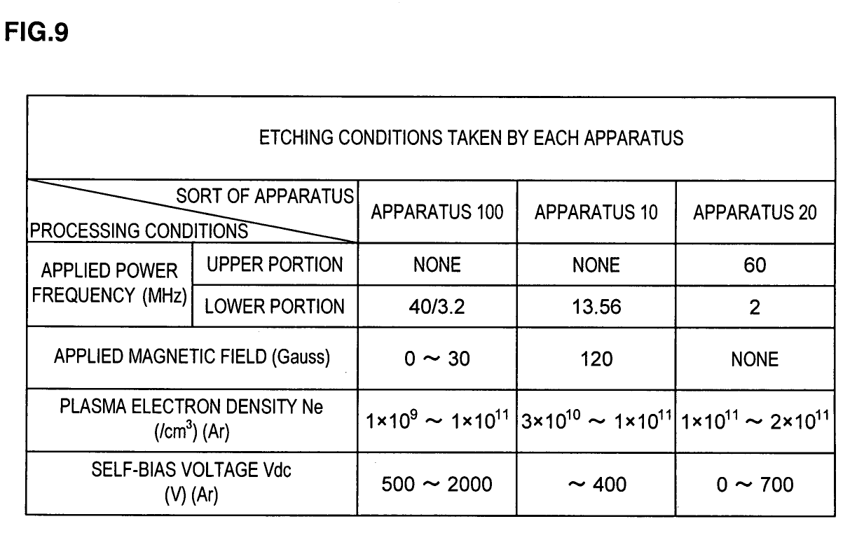

FIG. 9 is a table collectively showing etching conditions adopted in respective plasma etching apparatus. As shown in this figure, the etching condition as usually adopted by the plasma etching apparatus 10 is as follows. Namely, the frequency of the high frequency power applied to the lower electrode 106 is set to 23.56 MHz. The horizontal magnetic field strength is set to 120 Gauss. The plasma electron density Ne is within a range of 3×10¹⁰/cm³ to 1×10¹¹/cm³ under the condition that only Ar gas is supplied, and the self-bias voltage Vdc generated in the space in close vicinity to the lower electrode between both electrodes is 400V under the same condition as the above.

Furthermore, the etching condition as usually adopted by the plasma etching apparatus 20 is as follows. The high frequency power of 60 MHz is applied to the upper electrode 8 while the same of 2 MHz is applied to the lower electrode 106. The plasma electron density is in a range of 1×10¹¹/cm³ to 2×10¹¹/cm³ under the condition that only Ar gas is supplied but no magnetic field is applied, and the self-bias voltage Vdc generated in the space in close vicinity to the lower electrode between both electrodes is 700V under the same condition as the above.

On one hand, in the plasma etching apparatus 100 according to the present embodiment, the high frequency power of 2-system having frequencies of 40 MHz and 2 MHz is applied to the lower electrode 106 while the horizontal magnetic field is applied at a strength of 30 Gauss or less.

At this time, as explained in connection with dependency on each of the above-mentioned parameters, if each parameter is optimized in the area of the low plasma electron density and the high self-bias voltage Vdc, as the practical use of the apparatus 100 becomes in a wide range, it is deemed preferable that the plasma electron density Ne is in a range of 1×10⁹/cm³ to 1×10¹¹/cm³ under the condition that only Ar gas is supplied and the self-bias voltage generated in the space in close vicinity to the lower electrode 106 between upper and lower electrodes under the condition that only Ar gas is supplied is in a range of 500V to 2600V. It is more preferable that the plasma electron density Ne is in a range of 5×10⁹/cm³ to 3×10¹¹/cm³ under the condition that only Ar gas is supplied and the self-bias voltage generated in the space in close vicinity to the lower electrode 106 between upper and lower electrodes under the condition that only Ar gas is supplied is in a range of 900V to 1600V.

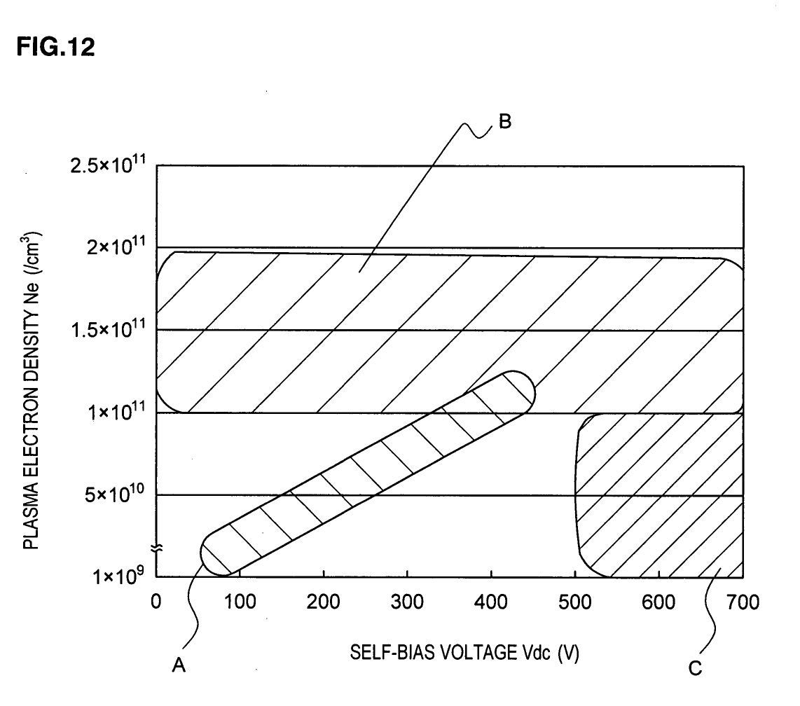

The area of these plasma electron density Ne and self-bias voltage where the etching process is performed, corresponds to the area C as described before in connection with FIG. 12. Therefore, it will be understood that the etching method and the plasma etching apparatus according to the invention is making use of the plasma state which is different from that which is used by the prior art method and apparatus.

(Etching with Processing Gas)

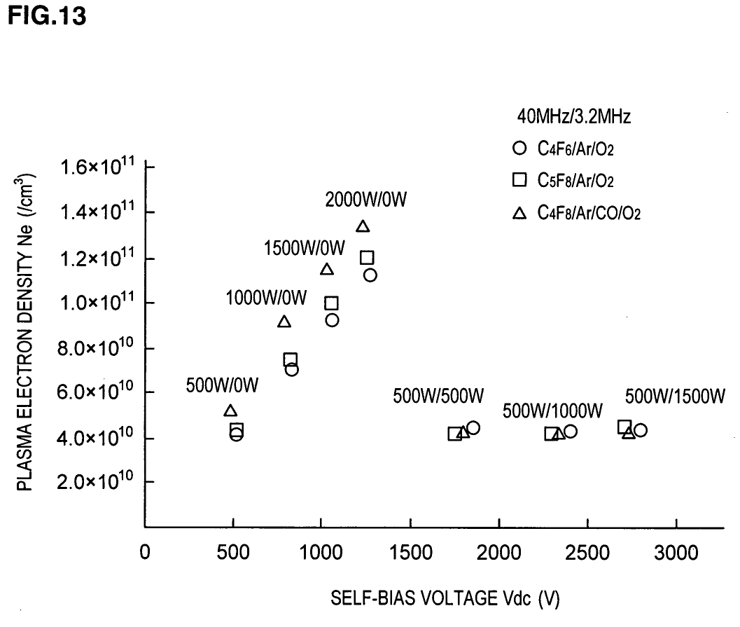

Here, there will be explained a result of etching process executed by the plasma etching apparatus 100 to which the processing gas is supplied. A magnet used in this process is not a type of generating a horizontal magnetic field vertical to the electric field but a type of generating a magnetic field of 10 Gauss surrounding the periphery of the semiconductor wafer, by which the plasma can be confined. The etching process is executed according to the following steps of first introducing the processing gas, applying the high frequency power having different high frequencies of 40 MHz and 3.2 MHz to the lower electrode, executing the etching process by changing the magnitude of the power to be applied, and measuring the self-bias voltage Vdc and the plasma electron density Ne. These measurement results are plotted in a graph as shown in FIG. 13, in which an abscissa indicates the self-bias voltage Vdc while an ordinate indicates the plasma electron density Ne.

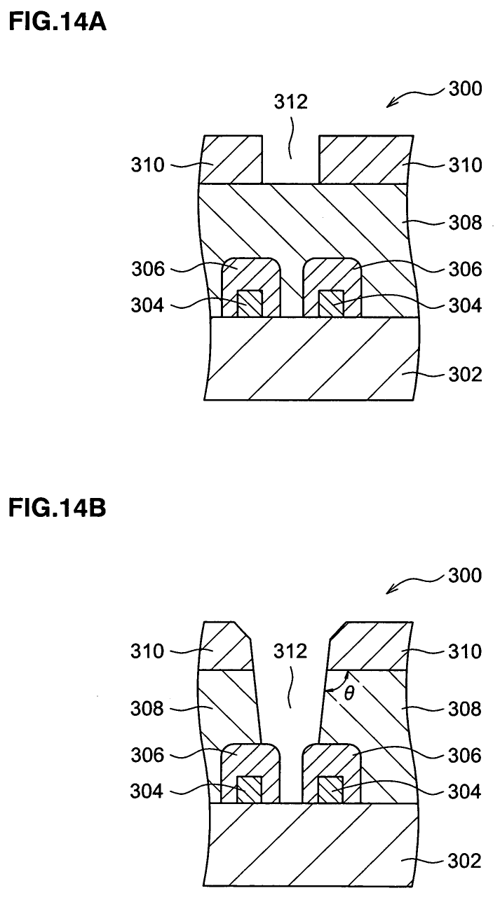

Here, the etching process is executed on a workpiece 300 as shown in FIG. 14A. This workpiece 300 is formed as follows. After forming a gate 304 on a silicon substrate 302 as a semiconductor substrate, a silicon nitride film layer 306 is formed as a protection layer to cover this gate 304. Then, a silicon oxide film layer 308 as an insulating film layer is formed to cover the entire surface, for example, by means of CVD (chemical vapor deposition) system. Furthermore, after painting a photo-resist over the silicon oxide film layer 308, a photo-resist pattern of a hole 312 is formed, thereby forming a photo-resist layer 310.

In the next, the a workpiece 300 formed in this way is etched by means of the plasma etching apparatus 100 such that the silicon oxide film layer 308 as an etching target layer is selectively etched relative to the silicon nitride film layer 306, thereby forming the hole 321 between gates 304.

Basic or reference conditions (1) for executing this etching process are set as follows. Each flow rate of C₄F₆ gas, Ar gas and 02 gas which are contained in the processing gas to be supplied is set to 28 sccm, 500 sccm and 20 sccm, respectively, the pressure inside the processing container set to 50 mTorr, the distance between the upper electrode 108 and the surface of the semiconductor wafer as a workpiece set to 27 mm, the heat transfer gas pressure at the backside surface set to 7 Torr at the center portion of it, and 40 Torr at the peripheral portion of it, the temperature of the upper electrode 108 set to 60° C., the temperature of the lower electrode set to 20° C., and the temperature at the side wall set to 60° C. The diameter of the semiconductor wafer as a workpiece is 8 inches.

Under this condition (1), at first, the high frequency power of 3.2 MHz was set to zero watts i.e. 0 W, in other words, no high frequency power of 3.2 MHz was applied to the lower electrode 106. Thus, the etching process was executed by applying only the following high frequency power of 40 MHz to the lower electrode 106 on the step basis in the order of 40 MHz 500 W (1.6 W/cm²), 40 MHz 1000 W (3.2 W/cm²), 40 MHz 1500 W (4.8 W/cm²), and 40 MHz 2000 W (6.4 W/cm²). In the next, another etching process was executed by applying the following high frequency power to the lower electrode 106 on the step basis in the order of 3.2 MHz 500 W (1.6 W/cm²), 3.2 MHz 1000 W (3.2 W/cm²), 3.2 MHz 1500 W (4.8 W/cm²), and 3.2 MHz 2000 W (6.4 W/cm²). At this time, the high frequency power of 40 MHz applied to the lower electrode 106 was fixed to 500 W (1.6 W/cm²). In these etching tests, there were measured the plasma electron density Ne and the self-bias voltage Vdc generated in the space in close vicinity to the lower electrode 106 between upper and lower electrodes, of which the results are plotted in FIG. 13.

Furthermore, a similar etching process was executed by changing the processing gas. To put it more concretely, an etching process was first executed under the above condition (1) by supplying the processing gas containing C₄F₆ gas of 11 sccm, Ar gas of 500 sccm and O₂ gas of 11 sccm and then, another etching process was executed under the above condition (1) by supplying the processing gas containing C₄F₆ gas of 10 sccm, Ar gas of 200 sccm, CO gas of 40 sccm, and 02 gas of 5 sccm. In these etching tests, there were measured the plasma electron density Ne and the self-bias voltage Vdc, of which results are plotted in FIG. 13.

According to the measurement results as shown in FIG. 13, while only the high frequency power of 40 MHz is applied to the lower electrode 106, if the level of the high frequency power is raised on the step basis of 500 W (1.6 W/cm²), 1000 W (3.2 W/cm²), 1500 W (4.8 W/cm²), and 2000 W (6.4 W/cm²), it is noted that the plasma electron density Ne rises in correspondence with the raised level of the high frequency power. As compared with this, while only the high frequency power of 3.2 MHz is applied to the lower electrode 106, if the level of the high frequency power is raised on the step basis of 500 W (1.6 W/cm²), 1000 W (3.2 W/cm²), 1500 W (4.8 W/cm²), and 2000 W (6.4 W/cm²), there is hardly shown any change in the plasma electron density Ne. Besides, according to the measurement results as shown in FIG. 13, it is noted that even if the sort of the processing gas is made different, there is shown the same tendency as the above.

In the next, an etching process is executed on a workpiece 300 as shown in FIG. 14 by using various combinations of the plasma electron density Ne and the self-bias voltage which are obtained based on the measurement results as shown in FIG. 13. In the following, there will be explained an etching rate, a taper angle of the hole as formed and an etching selection ratio which are measured through this etching process.

Basic conditions (2) for executing this etching process are set as follows. Each flow rate of C₄F₆ gas, Ar gas and O₂ gas which are contained in the processing gas to be supplied is set to 22 sccm, 500 sccm and 20 sccm, respectively, the pressure inside the processing container set to 50 mTorr, the distance between the upper electrode 108 and the surface of the semiconductor wafer as a workpiece set to 27 mm, the heat transfer gas pressure at the backside surface of the semiconductor wafer set to 7 Torr at the center portion of it and 40 Torr at the peripheral portion of it, the temperature of the upper electrode 108 set to 60° C., the temperature of the lower electrode 106 set to 20° C., and the temperature at the side wall set to 60° C.

Under this basic condition (2), an etching process was executed (a) at a low plasma electron density Ne (low density) and at a high self-bias voltage (high bias) as well. To put it more concretely, for example, the applied power to the lower electrode 106 is set to 40 MHz 500 W and 3.2 MHz 1600 W.

Furthermore, another etching process was executed (b) at a low plasma electron density Ne (low density) and at a low self-bias voltage (low bias) as well. To put it more concretely, for example, the applied power to the lower electrode 106 is set to 40 MHz 500 W and 3.2 MHz 800 W. Still further, another etching process was executed (c) at a high plasma electron density Ne (high density) and at a low self-bias (low bias). To put it more concretely, for example, the applied power to the lower electrode 106 is set to 40 MHz 1900 W and 3.2 MHz 800 W.

Still further, another etching process was executed (d) at a high plasma electron density Ne (high density) and at a high self-bias (high bias). To put it more concretely, for example, the applied power to the lower electrode 106 is set to 40 MHz 1900 W and 3.2 MHz 1600 W. Still further, another etching process was executed (e) at an intermediate plasma electron density Ne (intermediate density) and at an intermediate self-bias (intermediate bias). To put it more concretely, for example, the applied power to the lower electrode 106 was set to 40 MHz 1200 W and 3.2 MHz 1200 W.

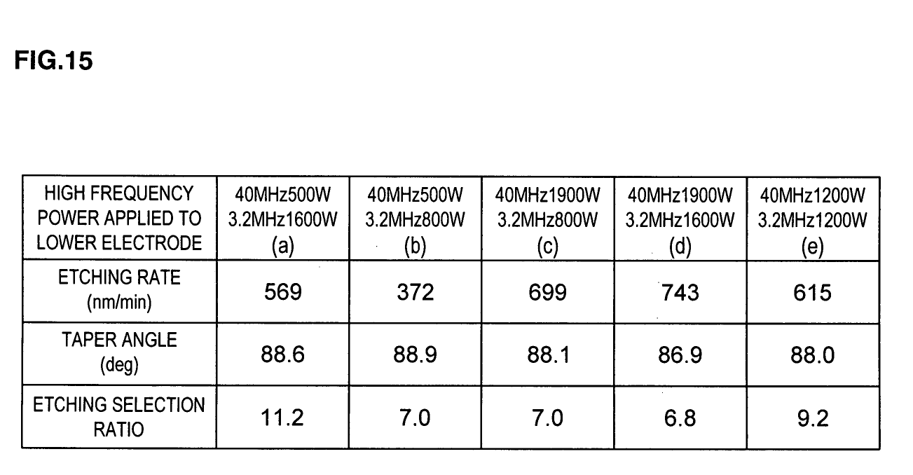

After having executed such etching processes as described above, an etching rate, a taper angle and an etching selection ratio were measured with regard to every etching process. The results of these measurements are summarized in a table shown in FIG. 15. In this figure, the etching rate was measured as an etching rate of a BPSG film which is an etching target film, the taper angle is measured as an inclination angle θ which is made by the side wall of the etched hole relative to a parallel line in parallel to the upper surface of the workpiece (see FIG. 14B), and the etching selection ratio is measured as the selection ratio of the BPSG film relative to a resist film as a mask material (i.e. Etching rate of BPGS film/Etching rate of Resist film).

According to the measurement results, when the etching process is executed (a) at a low plasma electron density Ne (low density) and at a high self-bias voltage (high bias) as well, it is noted that a relatively high etching rate can be obtained, but at the same time, it is also noted that the hole shows a well vertical shape and the selection ratio becomes large.

Like this, if the etching process is executed in a range of low electron density Ne as well as in the range of high self-bias voltage Vdc, it becomes possible take a large etching selection ratio of the BPSG film relative to the resist as the mask material film in the state where the etching rate of the BPSG film is high. Moreover, it becomes possible to form a hole, which has a flat, smooth and approximately vertical side wall, and of which the bottom area is secured enough relative to the area of the entrance opening of the hole.

For the practical standpoint of view, the low plasma electron density Ne is preferably in a range of 5×10⁹/cm³ to 1×10¹¹/cm³, more preferably, in a range of 8×10⁹/cm³ to 8×10¹⁰/cm³, and the self-bias voltage Vdc is preferably in a range of 1000V to 3000V, more preferably in a range of 2000V to 3000V. With regard to the power to be applied, the power at 40 MHz is preferably in a range of 100 W (0.32 W/cm²) to 100 W (3.2 W/cm²), and the power at 3.2 MHz is preferably in a range of 200 W (0.64 W/cm²) to 2000 W (6.4 W/cm²), more preferably, in a range of 500 W (1.64 W/cm²) to 2000 W (6.4 W/cm²).

### Embodiment 2

In the next, the second embodiment of the invention will be described with reference to the accompanying drawings. With regard to the first embodiment as descried above, it has been explained assuming that two kinds of high frequency powers are applied to the lower electrode 106 in the plasma etching apparatus 100, at two frequencies of 40 MHz and 3.2 MHz, for example. In the second embodiment, there will be explained about a case where two kinds of high frequency powers are applied to the lower electrode 106 at two frequencies of 100 MHz and 3.2 MHz, for example. Accordingly, a high frequency power source 122 of the plasma etching apparatus 100 according to the second embodiment is constituted such that it can change the high frequency power of 100 MHz.

Besides, a magnet 130 is constituted such that it can generate a magnetic field around the periphery of a semiconductor wafer W so as to confine the plasma and that the magnetic field strength becomes 10 Gauss or less.

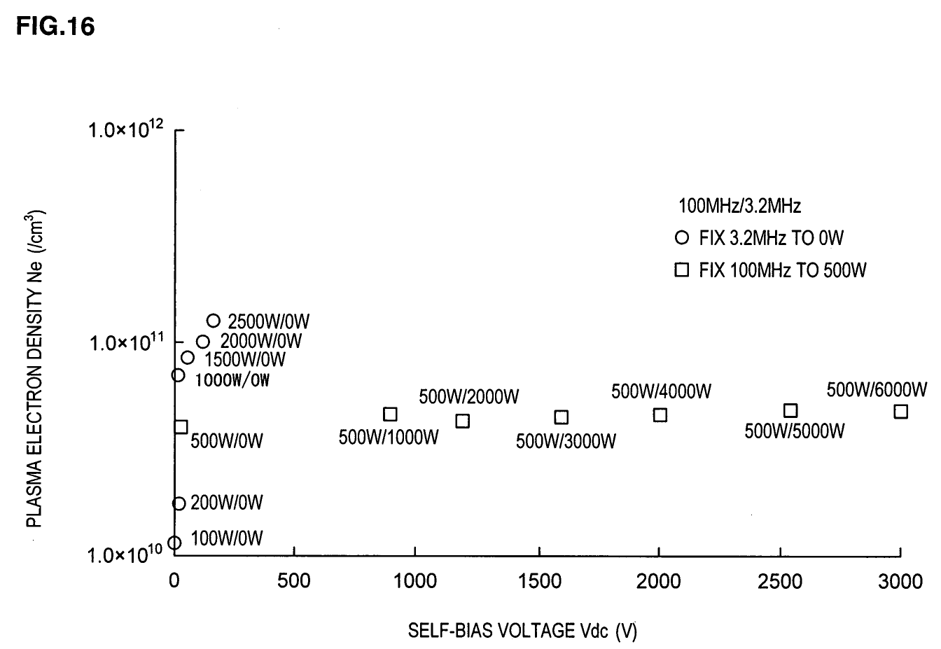

There will be explained the results of etching process which was executed by supplying the processing gas to the above plasma etching apparatus 100. At first, the processing gas was introduced and the frequency of the high frequency power was set to 100 MHz and 3.2 MHz. Then, etching processes were executed by changing the level of each high frequency power having one of frequencies as set above. Then, the self-bias voltage Vdc an the plasma electron density Ne generated at that time were measured, of which the results are plotted in a graph as shown in FIG. 16, in which an abscissa indicates the self-bias voltage Vdc while an ordinate indicates the plasma electron density Ne.

Here, the etching process is executed on the workpiece 200 using a semiconductor wafer of 300 mm thick as shown in FIG. 2, thereby forming a hole. Besides, each film thickness is as follows. For example, the mask layer 202 has a thickness of 620 nm and the etching target layer 204 has a thickness of 2 μm.

Basic conditions (3) for executing this etching process are set as follows. Each flow rate of C₄F₆ gas, Ar gas and O₂ gas which are contained in the processing gas to be supplied is set to 70 sccm, 1000 sccm and 47 sccm, respectively, the pressure inside the processing container set to 50 mTorr, the distance between the upper electrode 108 and the surface of the semiconductor wafer as a workpiece set to 40 mm, the heat transfer gas pressure at the backside surface set to 10 Torr at the center portion of it and 50 Torr at the peripheral portion of it, the temperature of the upper electrode 108 set to 60° C., the temperature of the lower electrode set 106 to 20° C., and the temperature at the side wall set to 60° C. The magnetic field strength of the magnet 130 is approximately 300 Gauss in order to let the magnetic field strength at the peripheral portion of the wafer be about 5 Gauss.

Under this condition (3), at first, the high frequency power of 3.2 MHz was set to zero watts i.e. 0 W, in other words, no high frequency power of 3.2 MHz was applied to the lower electrode 106. Thus, the etching process was executed by applying only the following high frequency power of 100 MHz to the lower electrode 106 in the order of 100 W (0.13 W/cm²), 200 W (0.27 W/cm²), 500 W (0.68 W/cm²), 1000 W (1.4 W/cm²), 1500 w (2.1 W/cm²), 2000 W (2.7 W/cm²) and 2500 w (3.1 W/cm²). In the next, another etching process was executed by applying the following high frequency power of 3.2 MHz to the lower electrode 106 in the order of 1000 W (1.4 W/cm²), 2000 W (2.7 W/cm²), 3000 W (4.2 W/cm²), 4000 W (5.6 W/cm²), 5000 W (6.2 W/cm²) and 6000 W (8.2 W/cm²). At this time, the high frequency power of 100 MHz applied to the lower electrode 106 was fixed to 500 W (0.68 W/cm²). In these etching tests, there were measured the plasma electron density Ne and the self-bias voltage Vdc generated in the space in close vicinity to the lower electrode 106 between upper and lower electrodes, of which the results are plotted in FIG. 16.

According to this measurement results, while only the high frequency power of 100 MHz is applied to the lower electrode 106, if the level of the high frequency power is raised in the order of 100 W, 200 W, 500 W, 1000 W, 2000 W and 2500 W, it is noted that the plasma electron density Ne rises in correspondence with the raised level of the high frequency power. As compared with this, while only the high frequency power of 3.2 MHz is applied to the lower electrode 106, if the level of the high frequency power is raised on the step basis of 500 W, 1000 W, 2000 W, 3000 W, 4000 W, 5000 W and 6000, it is noted that there is hardly shown any change in the plasma electron density Ne. Furthermore, it is noted that even if the sort of the processing gas is change from one to the other, for example, from C₄F₆ to C₄F₈, there is shown the same tendency as the above.

In the next, various etching processes other than those which were executed in the above etching tests, were executed by using various combinations of the level of the high frequency power of 100 MHz applied to the lower electrode and the level of the high frequency power of 3.2 Hz applied to the lower electrode. After executing each of these etching processes, there were measured the etching rate and the etching selection ratio of an etching target layer 204. Here, the etching selection ratio means a ratio of the etching rate of the etching target layer 204 to that of the mask layer 202, in other words, it is expressed as D3′/D2′ in terms of parameters shown in FIG. 2B.

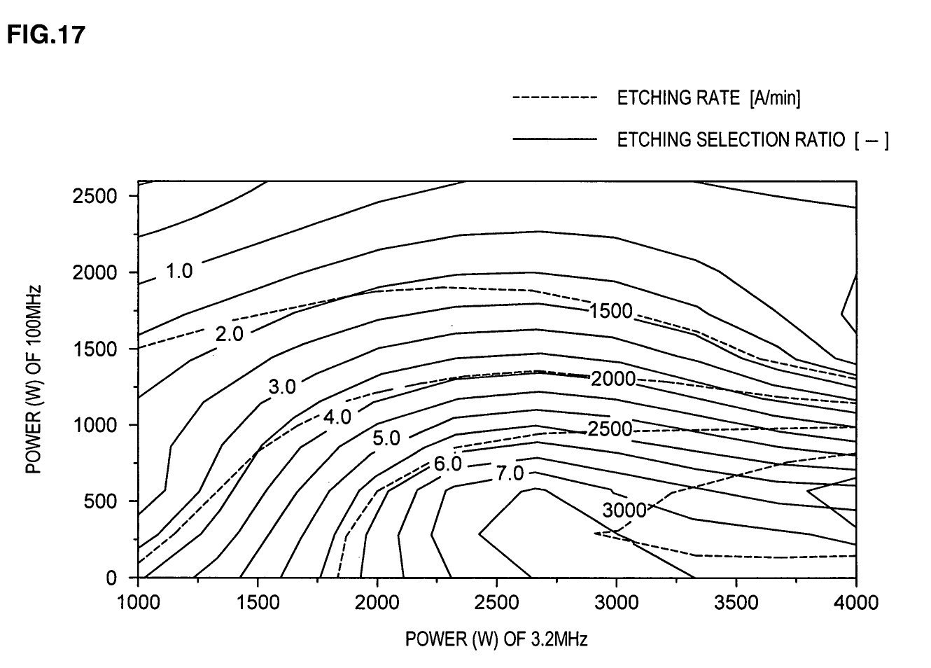

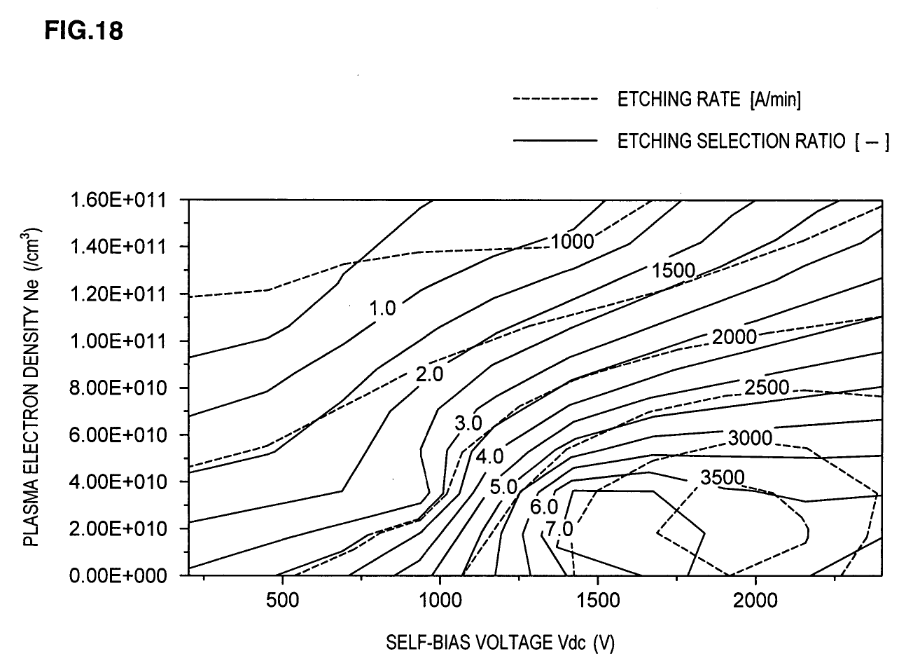

The results of the above measurements are shown in FIGS. 17 and 18. In FIG. 17, an abscissa indicates the magnitude (power) of the high frequency power of 3.2 MHz while an ordinate indicates the magnitude (power) of the high frequency power of 100 MHz, and a contour map as shown therein is made up of many contour lines (broken lines) drawn by connecting points having the same etching rate with each other and many contour lines (solid lines) drawn by connecting point having the same etching selection ratio with each other. In FIG. 18, an abscissa indicates the self-bias voltage Vdc while an ordinate indicates the plasma electron density Ne, and similar to FIG. 17, a contour map as shown therein is made up of many contour lines (broken lines) drawn by connecting points having the same etching rate with each other and many contour lines (solid lines) drawn by connecting point having the same etching selection ratio with each other.

Observing FIG. 17, it is noted that, in the range as measured i.e. the contour map as shown, if you move your eyes closely and closely toward a region around the lower right corner of the contour map, in other words, if the smaller the power of the high frequency power of 100 MHz becomes while the larger the power of the high frequency power of 3.2 MHz becomes, there become large both the etching rate and the etching selection ratio of the etching target film 204. This tendency may continue until the power of the high frequency power of 3.2 MHz goes up to approximately 6000 W.

Here, however, if the high frequency power (i.e. plasma electron density Ne) of 100 MHz is too small, the etching rate becomes excessively small, which is not appropriate. On the other hand, if the high frequency power of 3.2 MHz becomes excessively large, the etching selection ratio goes down, which is not appropriate.

For the practical standpoint of view, it is necessary that the etching rate of the etching target film 204 is 2000/min or more and the etching selection ratio of the same is 3 or more. Accordingly, it is preferable that each high frequency power to be combined is selected from the high frequency power of 3.2 MHz having the power in a range of 2000 W (2.7 W/cm²) to 6000 W (8.2 W/cm²) and the high frequency power of 100 MHz having the power in a range of 100 W (0.13 W/cm²) to 1000 W (1.4 W/cm²). That is, both the etching rate and the etching selection ratio of the etching target film 204 can be made large by using the combination of the power of each high frequency power in the respective ranges as described above.

Beside, although FIG. 18 is made from a different point of view, but it is noted from this figure that, in the range as measured i.e. the contour map as shown, if you move your eyes closely and closely toward a region around the lower right corner of the contour map, in other words, if the lower the plasma electron density Ne becomes while the higher the self-bias voltage Vdc becomes, there become large both the etching rate and the etching selection ratio of the etching target film 204.

For the practical standpoint of view, it is preferable that the plasma electron density Ne is in a range of 1×10¹⁰/cm³ to 8×10¹⁰/cm³ and the self-bias voltage Vdc is in a range of 1000V to 3000V. That is, both the etching rate and the etching selection ratio of the etching target film 204 can be made large by setting the etching rate and the etching selection ratio of the etching target film 204 to be in the respective ranges as described above.

As explained in detail above, according to the plasma etching apparatus 100, if the etching process is executed under such a condition that the low plasma electron density Ne and the high self-bias voltage Vdc are in respective appropriate ranges and the magnetic field strength is low, it becomes possible to take a high value with regard to the etching rate and the etching selection ratio as well, and to form a hole having an appropriate shape.

Here, when only Ar gas is supplied for example, respect ranges of the low plasma electron density Ne and the high self-bias voltage Vdc are in a range of 1×10⁹/cm³ to 1×10¹¹/cm³ for the plasma electron density Ne and in a range of 500V to 2000V for the self-bias voltage Vdc, respectively.

Besides, where the processing gas is supplied and two kinds of high frequency powers of 40 MHz and 3.2 MHz are applied to the lower electrode as has been done in the first embodiment, from the practical standpoint of view, it is preferable that the plasma electron density Ne is in a range of 8×10⁹/cm³ to 8×10¹⁰/cm³ and the self-bias voltage Vdc is in a range of 1000V to 3000V, more preferable that the plasma electron density Ne is in a range of 5×10⁹/cm³ to 1×10¹¹/cm³ and the self-bias voltage Vdc is in a range of 2000V to 3000V. As to the applied high frequency power, it is preferable that the power of the high frequency of 40 MHz is in a range of 100 W (0.32 W/cm²) to 1000 W (3.2 W/cm²) and the power of the high frequency of 3.2 MHz is in a range of 200 W (0.64 W/cm²) to 2000 W (6.4 W/cm²), more preferable that the power of the high frequency of 3.2 MHz is in a range of 500 W (1.6 W/cm²) to 2000 W (6.4 W/cm²).

Besides, where two kinds of high frequency powers of 100 MHz and 3.2 MHz are applied to the lower electrode as has been done in the second embodiment, from the practical standpoint of view, it is preferable that the plasma electron density Ne is in a range of 1×10¹⁰/cm³ to 8×10¹⁰/cm³ and the self-bias voltage Vdc is in a range of 1000V to 3000V. As to the applied high frequency power, it is preferable that the power of the high frequency of 40 MHz is in a range of 100 W (0.13 W/cm²) to 1000 W (1.4 W/cm²) and the power of the high frequency of 3.2 MHz is in a range of 2000 W (2.7 W/cm²) to 6000 W (8.2 W/cm²).

Besides, with regard to the low magnetic field strength, it is preferable that the etching processing is executed such that the magnetic field strength over a workpiece becomes 10 Gauss or less, for example. In this case, it is preferable that the magnetic field is generated near the processing container so as to confine the plasma. In the present embodiment, in order to achieve the above preferable magnetic field, a multi-pole magnet (MPM) is constituted by arranging a plurality of magnets 130 such that their N and S poles alternately surround the periphery of the processing container.

While the invention has been shown and described in detail with respect to preferred embodiments of the etching method and the plasma etching apparatus according thereto by referring to the accompanying drawings, the present invention is not limited to those examples. It is apparent that persons skilled in the art make various changes and modifications within the category of technical thoughts as recited in the scope of claim for patent, and it is understood that those changes and modifications naturally belong to the technical scope of the invention.

As to the etching target film, it has been explained by using the silicon oxide film as an example so far, but the invention is not limited to it. The invention is applicable to other oxide films containing silicon, for example carbon added silicate (SiOC) film, hydrogen added silicate (SiOH) film, fluorine added silicate (SiOF) film, and other films having a low dielectric constant.

Besides, the present invention is applicable to a plasma etching apparatus other than the plasma etching apparatus of the parallel flat pole (parallel flat plate electrode) type, for example, a plasma etching apparatus of the inductive coupling type, a plasma etching apparatus of the electron cyclotron resonance type and so forth.

In the etching process test in the first and the second embodiments as described above, the distance between the upper and the lower electrodes is set to 27 mm, but the invention is not always limited to this value. However, if the distance between electrodes is set to an excessively small value, there might be caused such a problem that the difference in the pressure difference of the processing gas at the surface of the workpiece (i.e. pressure difference between the center portion and the peripheral portion) becomes large, which comes to damage etching uniformity. Thus, it is preferable that the distance between electrodes is set in a range of 30 mm to 50 mm.

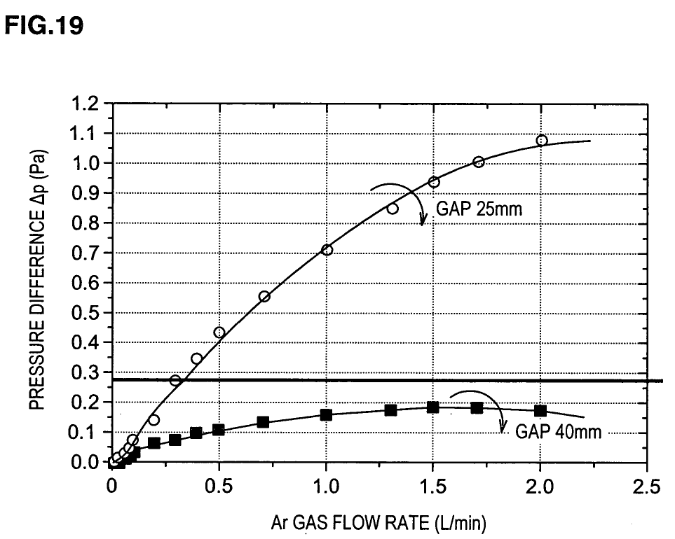

This will be explained referring to FIG. 19, which is a graph showing a relation between a plasma gas flow rate and a pressure difference Δp between the center portion and the peripheral portion of a wafer, wherein Ar gas is used a plasma gas and the electrode gaps of 25 mm and 40 mm are used as parameters. As shown in this figure, the pressure difference Δp becomes small when the gap is set to 40 mm comparing with when it is set to 25 mm. Besides when the gap is set to 25 mm, the pressure difference Δp shows has a tendency to abruptly rise together with the rise of the Ar gas flow rate, for example, when the gas flow rate is 0.3 L/min or so, the pressure difference Δp quickly exceeds a preferable pressure difference of 0.27 Pa (2 mTorr). Comparing with this, when the gap is set to 40 mm, the pressure difference Δp becomes smaller than 0.27 Pa (2 mTorr) regardless of the gas flow rate. Accordingly, it will be expected that a preferable pressure difference Δp would be obtained by setting a gap to 35 mm or more.

According to Paschens' law, a firing potential Vs takes a minimum value (Paschen minimum value) when the product pd of a gas pressure p and a distance d between electrodes takes a certain value. As the larger the frequency of the high frequency power becomes, the smaller the value of pd taking the Paschen minimum value becomes small. Accordingly, in case of the invention, when the frequency of the high frequency power is large, in order to make the firing potential Ve small for achieving easy and stabilized firing, it is required to make the distance d between electrodes small if the gas pressure p is constant. Because of this, in the invention, it is preferable to set the distance d to 500 mm or less. Besides, if the distance d between electrodes is set to 500 mm or less, the residence time of the gas in the processing chamber can be shortened, thus reaction products being efficiently exhausted and the sudden etching stop being effectively reduced or prevented.

As has been described above so far, according to the invention, since the etching process is executed by applying high frequency powers having different frequencies of two systems to the lower electrode of the plasma etching apparatus as well as by using low plasma electron density Ne, high self-bias voltage Vdc and low magnetic field strength, both the etching rate of the etching target film and the etching selection ratio of the etching target film relative to a mask material film can be made large and, moreover, it is possible to form a hole which has an approximately vertical and smooth side wall and a bottom area secured enough relative to the entrance opening area of the hole.

### Possibility of Industrial Use

The invention is applicable to an etching method and a plasma etching apparatus as used in a manufacturing process of semiconductor elements and devices, especially applicable to an etching method and a plasma etching apparatus which are capable of improving the etching selection ratio of an etching target film relative to a mask material.

1. An etching method for etching an etching target film formed at a workpiece comprising the steps of: introducing a processing gas into an air tight processing container provided with a pair of upper and lower electrodes arranged to oppose to each other; applying the high frequency power to at least one of said upper and lower electrodes, thereby converting said processing gas into plasma; and etching said etching target film formed at said workpiece mounted on said lower electrode by using a mask material patterned in advance as a mask,
wherein an electron density in the plasma converted from said processing gas is in a range of 8×10⁹/cm³ to 8×10¹⁰/cm³; and
the self-bias voltage generated in the space in close vicinity to said lower electrode between said both electrodes is in a range of 2000V to 3000V.

2. An etching method as claimed in claim 1, wherein there are applied to said lower electrode the first high frequency power having the first frequency and the second high frequency power having the second high frequency lower than said first frequency.

3. An etching method as claimed in claim 2, wherein said first frequency is 40 MHz and said second frequency is 3.2 MHz.

4. An etching method as claimed in claim 3, wherein the power density of 40 MHz applied to said lower electrode is in a range of 0.32 W/cm² to 3.2 W/cm² and the power density of 3.2 MHz applied to said lower electrode is in a range of 1.6 W/cm² to 6.4 W/cm².

5. An etching method for etching an etching target film formed at a workpiece comprising the steps of: introducing a processing gas into an air tight processing container provided with a pair of upper and lower electrodes arranged to oppose to each other; applying the high frequency power to at least one of said upper and lower electrodes, thereby converting said processing gas into plasma; and etching said etching target film formed at said workpiece mounted on said lower electrode by using a mask material patterned in advance as a mask,
wherein there are applied to said lower electrode the first high frequency power having the first frequency of 40 MHz, of which the power density is in a range of 0.32 W/cm² to 3.2 W/cm² and the second high frequency power having the second high frequency of 3.2 MHz, of which the power density is in a range of 1.6 W/cm² to 6.4 W/cm².

6. An etching method as claimed in claim 1, wherein said etching target film is an oxide film containing silicon.

7. An etching method as claimed in claim 6, wherein said etching is executed to selectively etch said oxide film containing silicon relative to a silicon nitride film.

8. A plasma etching apparatus in which a processing gas is introduced into an air tight processing container provided with a pair of upper and lower electrodes arranged to oppose to each other, the high frequency power is applied to at least one of said upper and lower electrodes, thereby converting said processing gas into plasma, and said etching target film formed at said workpiece mounted on said lower electrode is etched by using a mask material patterned in advance as a mask,
wherein an electron density in the plasma converted from said processing gas is in a range of 8×10⁹/cm³ to 8×10¹⁰/cm³;
the self-bias voltage generated in the space in close vicinity of said lower electrode between said both electrodes is in a range of 2000V to 3000V; and
there are applied to said lower electrode the first high frequency power having the first frequency and the second high frequency power having the second high frequency lower than said first frequency.

9. A plasma etching apparatus as claimed in claim 8, wherein said first frequency is 40 MHz and said second frequency is 3.2 MHz.

10. A plasma etching apparatus as claimed in claim 8, wherein the power density of 40 MHz applied to said lower electrode is in a range of 0.32 W/cm² to 3.2 W/cm² and the power density of 3.2 MHz applied to said lower electrode is in a range of 1.6 W/cm² to 6.4 W/cm².

11. A plasma etching apparatus in which a processing gas is introduced into an air tight processing container provided with a pair of upper and lower electrodes arranged to oppose to each other, the high frequency power is applied to at least one of said upper and lower electrodes, thereby converting said processing gas into plasma, and said etching target film formed at said workpiece mounted on said lower electrode is etched by using a mask material patterned in advance as a mask,
wherein there are applied to said lower electrode the first high frequency power having the first frequency of 40 MHz, of which the power density is in a range of 0.32 W/cm² to 3.2 W/cm² and the second high frequency power having the second high frequency of 3.2 MHz, of which the power density is in a range of 1.6 W/cm² 6.4 W/cm².

12. An etching method for etching an etching target film formed at a workpiece comprising the steps of: introducing a processing gas into an air tight processing container provided with a pair of upper and lower electrodes arranged to oppose to each other; applying the high frequency power to at least one of said upper and lower electrodes, thereby converting said processing gas into plasma; and etching said etching target film formed at said workpiece mounted on said lower electrode by using a mask material patterned in advance as a mask,
wherein an electron density in the plasma converted from said processing gas is in a range of 1×10¹⁰/cm³ to 8×10¹⁰/cm³; and
the self-bias voltage generated in the space in close vicinity to said lower electrode between said both electrodes is in a range of 1000V to 3000V.

13. An etching method as claimed in claim 12, wherein there are applied to said lower electrode the first high frequency power having the first frequency and the second high frequency power having the second high frequency lower than said first frequency.

14. An etching method as claimed in claim 13, wherein said first frequency is 100 MHz and said second frequency is 3.2 MHz.

15. An etching method as claimed in claim 14, wherein the power density of 100 MHz applied to said lower electrode is in a range of 0.13 W/cm² to 1.4 W/cm² and the power density of 3.2 MHz applied to said lower electrode is in a range of 2.7 W/cm² to 8.2 W/cm².

16. An etching method for etching an etching target film formed at a workpiece comprising the steps of: introducing a processing gas into an air tight processing container provided with a pair of upper and lower electrodes arranged to oppose to each other; applying the high frequency power to at least one of said upper and lower electrodes, thereby converting said processing gas into plasma; and etching said etching target film formed at said workpiece mounted on said lower electrode by using a mask material patterned in advance as a mask,
wherein there are applied to said lower electrode the first high frequency power having the first frequency of 100 MHz, of which the power density is in a range of 0.13 W/cm² to 1.4 W/cm² and the second high frequency power having the second high frequency of 3.2 MHz, of which the power density is in a range of 2.7 W/cm² to 8.2 W/cm².

17. An etching method as claimed in claim 12, wherein said etching target film is an inorganic insulating film.

18. A plasma etching apparatus in which a processing gas is introduced into an air tight processing container provided with a pair of upper and lower electrodes arranged to oppose to each other, the high frequency power is applied to at least one of said upper and lower electrodes, thereby converting said processing gas into plasma, and said etching target film formed at said workpiece mounted on said lower electrode is etched by using a mask material patterned in advance as a mask,
wherein an electron density in the plasma converted from said processing gas is in a range of 1×10¹⁰/cm³ to 8×10¹⁰/cm³;
the self-bias voltage generated in the space in close vicinity to said lower electrode between said both electrodes is in a range of 1000V to 3000V; and
there are applied to said lower electrode the first high frequency power having the first frequency and the second high frequency power having the second high frequency lower than said first frequency.

19. A plasma etching apparatus as claimed in claim 18, wherein said first frequency is 100 MHz and said second frequency is 3.2 MHz.

20. A plasma etching apparatus as claimed in claim 19, wherein the power density of 100 MHz applied to said lower electrode is in a range of 0.13 W/cm² to 1.4 W/cm² and the power density of 3.2 MHz applied to said lower electrode is in a range of 2.7 W/cm² to 8.2 W/cm².

21. A plasma etching apparatus in which a processing gas is introduced into an air tight processing container provided with a pair of upper and lower electrodes arranged to oppose to each other, the high frequency power is applied to at least one of said upper and lower electrodes, thereby converting said processing gas into plasma, and said etching target film formed at said workpiece mounted on said lower electrode is etched by using a mask material patterned in advance as a mask,
wherein there are applied to said lower electrode the first high frequency power having the first frequency of 100 MHz, of which the power density is in a range of 0.13 W/cm² to 1.4 W/cm² and the second high frequency power having the second high frequency of 3.2 MHz, of which the power density is in a range of 2.7 W/cm² to 8.2 W/cm².
